(19) United States
(12) Patent Application Publication
(10) Pub. No.: US 2008/0174016 A1
(43) Pub. Date: Jul. 24, 2008

(54) Flexible Printed Wiring Board and Semiconductor Device

(75) Inventors: Tetsuro Sato, Ageo-shi (JP); Makoto Yamagata, Tokyo (JP); Noriaki Iwata, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Tokyo (JP)

(21) Appl. No.: 11/965,404

(22) Filed: Dec. 27, 2007

(30) Foreign Application Priority Data
Dec. 28, 2006 (JP) 2006-355795

(51) Int. Cl. H01L 23/48; B32B 3/00

(52) U.S. Cl. 257/741; 428/209; 257/E23.01

(57) ABSTRACT

A flexible printed wiring board is characterized by a laminate formed by directly laminating an electrodeposited copper foil having S side and M side, each of S side and M side having a different surface roughness, the surface roughness (Rzjis) of the deposition plain side being 1.0 μm or less, and the glossiness of the M side [Gs(60°)] being 400 or more, on a surface of an insulating layer being a substrate layer made of a resin having both of an imide structure and an amide structure in the molecule; and forming a wiring pattern by etching the electrodeposited copper foil. By using a resin having both of an imide structure and an amide structure in the molecule as the insulating layer, a flexible printed wiring board having excellent properties such as mechanical properties, heat resistance, alkali resistance and the like, especially a COF substrate is provided.

### BACKGROUND OF THE INVENTION

1. Field of the Invention

The present invention relates to a flexible printed wiring board and a semiconductor device using, as an insulating film, a substrate film made of a resin having both of an imide structure and an amide structure in the molecule. More particularly, the present invention relates to a flexible printed wiring board and a semiconductor device formed by using a substrate film made of a resin having both of an imide structure and an amide structure in the molecule, in place of a polyimide film which has been widely used as an insulating substrate.

2. Description of the Related Art

In order to mount electronic components, printed wiring boards having flexibility are used. Such printed wiring boards having flexibility are generally formed by forming a laminate of flexible films having insulation properties such as polyimide films and conductive metal foils such as electrodeposited copper foils, forming a layer of photosensitive resins on the surface of conductive metal foils that is the surface of the laminate, forming patterns of cured photosensitive resins into a desired shape through light exposure and sensitization, and etching the conductive metal foils using the patterns as masking materials.

In recent printed wiring boards, in order to mount electronic components with higher density, without forming device holes for mounting electronic components in flexible films having insulation properties as in conventional approach, electronic components are mounted on printed wiring boards by forming a thin insulating film, and heating leads formed on the printed wiring boards and bump electrodes formed on the electronic components using bonding tools through the thin insulating film. Printed wiring boards used in such a bonding method are distinguished from printed wiring boards having device holes and generally called as COF (Chip On Film) substrates.

In such COF substrates, since electrical connection between bump electrodes formed on the electronic components and leads is made by abutting bonding tools for mounting electronic components on the back side of COF substrates, and heating leads formed on the COF substrates, high heat resistance is required for resins used as an insulating film, and in practice, polyimide that is considered to have the highest heat resistance among resins is used as an insulating film forming COF substrates.

Polyimide used as an insulating film of COF substrates is considered to be the best resin for substrate films of printed wiring boards from the viewpoint of heat resistance, because polyimide has very excellent heat resistance.

However, polyimide resin does not exhibit the solubility for most solvents, and therefore, when producing polyimide films, solving or dispersing polyamic acids which are polyimide precursors exhibiting slight solubility for N-methyl-2-pyrrolidone (NMP), dimethylformamide (DMF) and the like into a solvent such as DMF to form a film and performing in situ ring closure reaction of the polyamic acids by baking are required. Furthermore, since baking and ring closure of polyamic acid are required as described above, polyimide films have problems that their thickness is restricted for baking; when used solely, thinner polyimide films can not be produced; and when being too thick, imidization reaction hardly proceeds uniformly as a whole, although they have very excellent heat resistance.

In addition, particularly in recent printed wiring boards, insulating films are becoming thinner and thinner, and printed wiring boards having such very thin insulating films as less than 10 μm have been already used. When producing such very thin insulating films with polyimide films, production of such thin polyimide films is very difficult by themselves. Therefore, in general, a two-layer laminate (CCL) made of a conductive metal foil and a polyimide layer is manufactured by applying DMF solution (or dispersion) of a polyamic acid on the surface of the conductive metal foil, baking with the conductive metal foil at a temperature of 360° C. or more and performing ring closure reaction of the polyamic acid on the surface of the conductive metal foil, and then a wiring pattern is formed by etching the conductive metal foil selectively. Incidentally, when such a laminate is produced, a through hole such as a device hole in the conductive metal foil can not be formed, because a solution containing the polyamic acid is applied on the surface of the conductive metal foil.

When forming a two-layer laminate as described above, heating of the laminate at a temperature of 360° C. or more at which ring closure reaction of the polyamic acid stably proceeds is needed in order to promote ring closure reaction of the applied polyamic acid promptly and to form a polyimide layer. Incidentally, in the laminate described above, the conductive metal foil is laminated. If the conductive metal foil is, for example, an electrodeposited copper foil, the electrodeposited copper foil is an aggregate of many copper particles deposited from an electrolyte. In such an electrodeposited copper foil that is an aggregate of metal particles, recrystallization may occur by heating even at the temperature of ring closure reaction of polyamic acid described above which is lower than the melting point of the metal. Accordingly, properties of the electrodeposited copper foil may vary significantly by recrystallization of copper in the electrodeposited copper foil. That is, when copper crystal structure varies by recrystallization, physical properties, chemical properties, electrical properties and the like of the copper foil may vary significantly.

By the way, as a heat resistant resin having electrical insulating properties, polyamide-imide has been known and has been proposed for an insulating film forming resin of printed wiring boards. This polyamide-imide resin has heat resistance of 260° C. or more, but it is thermoplastic. Therefore this resin is not used for an insulating film of printed wiring boards which are required to undergo high-temperature heating processes such as bonding and solder reflowing.

However, due to recent improvement in polyamide-imide film and changes in technology for mounting electronic components, polyamide-imide is used more and more widely as an insulating film for film carrier used in mounting electronic components.

For example, in Japanese Patent Laid-Open Publication No. 2005-325329, a metal laminate using polyamide-imide represented by specific formulas is disclosed. It is described that such polyamide-imide as disclosed in Japanese Patent Laid-Open Publication No. 2005-325329 can be used for a two-layered printed wiring board.

By the way, apart from the improvement of synthetic resin materials for an insulating film described above, electrodeposited copper foils to be used have been improved in various ways. For example, a dense electrodeposited copper foil has been conventionally produced through adjusting formed particle size by blending glue and the like to a copper foil electrolyte. It is shown that such an electrodeposited copper foil that is a dense aggregate of particles has very good surface state and can form excellent circuit boards (for example, WO2006/106956 A1 pamphlet).

The electrodeposited copper foil described in WO2006/106956 A1 pamphlet is different from conventional electrodeposited copper foils, and is a copper foil having significantly reduced surface roughness achieved by lowering surface roughness on the deposition plane through adjusting the particle diameter of the deposited copper particles and furthermore by lowering total surface waviness of the deposition plane of the electrodeposited copper foil. By using this type of electrodeposited copper foils having low surface roughness, manufacturing of printed wiring boards with smaller pitch width can be possible. However, if crystal structure of copper particles constituting an electrodeposited copper foil changes by recrystallization, the change may affect the surface state of the electrodeposited copper foil. In addition, the electrodeposited copper foil described in WO2006/106956 A1 pamphlet is excellent in mechanical properties such as tensile strength because of a large crystal particle diameter of copper as described above, but there is concern that such properties may be impaired by recrystallization through heating.

Although a polyamide-imide resin having a specific biphenyl structure is disclosed in Japanese Patent No. 3097704 publication, the resin is not sufficient as a resin forming an insulating layer of a flexible printed wiring board from the viewpoint of chemical resistance such as alkali resistance and acid resistance and heat resistance.

As described above, a resin forming an insulating layer of a conventional flexible printed wiring board is polyimide, which has extremely high heat resistance. However, polyimide is not sufficient in properties such as chemical resistance. In particular, when more dense wiring pattern is to be formed by changing crystal size of a copper foil for forming the wiring pattern, conventional polyimide resin can not provide sufficient properties. In addition, there is a problem that if commonly used polyamide-imide resins and a polyamide-imide resin described in Japanese Patent No. 3097704 publication are used, they can not provide expected properties.

### SUMMARY OF THE INVENTION

An object of the present invention is to provide a flexible printed wiring board using a resin having both of an imide structure and an amide structure in the molecule in an insulating layer.

More particularly, an object of the present invention is to provide a flexible printed wiring board having various excellent properties such as mechanical properties and heat resistance, its insulating layer being a substrate layer made of a resin having both of an imide structure and an amide structure in the molecule.

Another object of the present invention is to provide a semiconductor device using the flexible printed wiring board described above.

The flexible printed wiring board of the present invention is characterized that a laminate formed by directly laminating an electrodeposited copper foil having S side and M side, each of S side and M side having a different surface roughness, and the surface roughness of the M side being 5 μm or less, on a surface of a substrate layer made of a resin having both of an imide structure and an amide structure in the molecule; and forming a wiring pattern by etching the electrodeposited copper foil

Also, the flexible printed wiring board of the present invention is characterized that a laminate formed by directly laminating an electrodeposited copper foil having S side and M side, each of S side and M side having a different surface roughness, the surface roughness (Rzjis) of the M side of a deposition plain being 1.0 μm or less, and the glossiness of the M side [Gs(60°)] being 400 or more, on a surface of a substrate layer made of a resin having both of an imide structure and an amide structure in the molecule; and forming a wiring pattern by etching the electrodeposited copper foil.

In the flexible printed wiring board of the present invention, preferably, the resin forming the substrate layer is a resin formed by an aromatic diisocyanate, an aromatic tricarboxylic acid or its anhydride, an aromatic dicarboxylic acid and its anhydride, and/or an aromatic tetracarboxylic acid and its anhydride; and having an imide structure and an amide structure in the molecule.

Furthermore, in the flexible printed wiring board of the present invention, it is preferable that a structure represented by the following formula (1) is formed in the resin for forming the substrate layer,

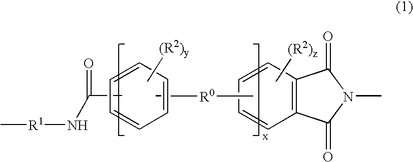

In the above formula (1), R⁰ represents any of a divalent hydrocarbon group, a carbonyl group, an oxygen atom, a sulfur atom, sulfur oxide and a single bond; R¹ represents a divalent aromatic hydrocarbon group optionally having an aliphatic hydrocarbon group; R² each independently represents a monovalent hydrocarbon group; x is 0 or 1; y is any of 0, 1, 2, 3 and 4; and z is any of 0, 1, 2 and 3.

Also, in the flexible printed wiring board of the present invention, it is preferable that at least one structure selected from the group consisting of structures represented by the following formulas (2) to (5) is formed in the resin for forming the substrate layer.

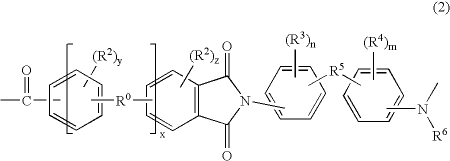

In the above formula (2), R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; R⁵ represents a divalent hydrocarbon group; R⁶ represents a hydrogen atom or a monovalent aliphatic hydrocarbon group or forms a polyimide structure in cooperation with N; n and m each is independently any of 0, 1, 2, 3 and 4; x is 0 or 1; y is any of 0, 1, 2, 3 and 4; and z is any of 0, 1, 2 and 3.

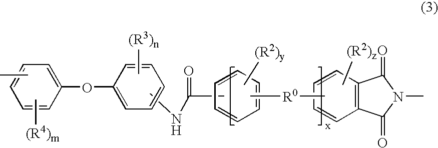

In the above formula (3), R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; x is 0 or 1; y is any of 0, 1, 2, 3 and 4; and z is any of 0, 1, 2 and 3.

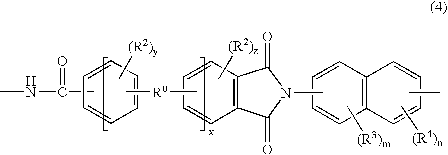

In the above formula (4), R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; x is 0 or 1; y is any of 0, 1, 2, 3 and 4; and z is any of 0, 1, 2 and 3.

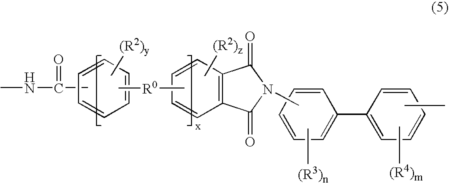

In the above formula (5), R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; x is 0 or 1; y is any of 0, 1, 2, 3 and 4; and z is any of 0, 1, 2 and 3.

### BRIEF DESCRIPTION OF THE DRAWINGS

FIG. 1 shows an electron microscope photograph of the cross-section of inner leads formed from a low-profile electrodeposited copper foil and its traced drawing.

FIG. 2 shows an electron microscope photograph of the surface of a low-profile electrodeposited copper foil.

FIG. 3 is a cross-sectional view showing the state of copper particles constituting the conventional electrodeposited copper foil.

### DESCRIPTION OF THE PREFERRED EMBODIMENTS

The flexible printed wiring board of the present invention has, as an insulating layer, a substrate layer made of a resin having both of an imide structure and an amide structure in the molecule. Although the resin having both of an imide structure and an amide structure in the molecule used herein has high heat resistance, it can form a film at a temperature of approximately 250° C. This temperature is by about 100° C. lower than the baking temperature of polyimide which has been conventionally used in insulating films. Accordingly, even when an insulating film is formed by applying a solution containing the resin described above having both of an imide structure and an amide structure in the molecule and forming an insulating film on electrodeposited copper foil having low surface roughness, recrystallization of copper particles in the electrodeposited copper foil hardly occurs by the heating during the film forming, and excellent properties inherent to the electrodeposited copper foil are maintained.

Also, the resin having both of an imide structure and an amide structure in the molecule is thermoplastic but has very high melting point or softening point. And when electrical connection by heating leads on the front side and bump electrodes formed on electronic components through the insulating layer from the back side of the insulating layer is performed as in COF substrates, this heating does not cause damage to the insulating layer that is a substrate layer made of a resin having both of an imide structure and an amide structure in the molecule.

In addition, the substrate layer can have almost the same linear expansion coefficient as that of the copper foil, and deformation of the printed wiring board due to different linear expansion coefficients hardly occurs.

Furthermore, this resin having both of an imide structure and an amide structure in the molecule has excellent chemical resistance. For example, when this resin contacts with a strong alkali washing liquid for surface cleaning during the production process of the printed wiring board, the insulating film of the printed wiring board is not denatured, so that a strong alkali washing liquid having stronger washing power can be contacted and printed wiring boards can be efficiently manufactured by making contact time with a strong alkali washing liquid shorter. Also, since the contact time with an alkali washing liquid is short, the alkali washing liquid hardly affects the printed wiring boards.

Moreover, when a metal layer is laminated on a substrate layer made of a resin having both of an imide structure and an amide structure in the molecule, diffusion of the laminated metal into the substrate layer is smaller compared with a substrate layer made of a polyimide, and insulating properties of the substrate layer hardly vary.

Furthermore, properties of this resin such as water absorption, heat resistance and formability can be adjusted by adjusting the ratio of an imide structure to an amide structure in the molecule.

The flexible printed wiring board of the present invention is specifically explained as follows.

The flexible printed wiring board of the present invention comprises an insulating film made of a resin having both of an imide structure and an amide structure in the molecule and a wiring pattern formed by etching selectively an electrodeposited copper foil disposed on the surface of the insulating film. The insulating film is a substrate layer in the flexible printed wiring board of the present invention, and the substrate layer is also an insulating layer.

The flexible printed wiring board of the present invention is formed by using a laminate in which a substrate layer made of a resin having both of an imide structure and an amide structure in the molecule to be an insulating layer, and a given copper foil are directly laminated.

A resin having both of an imide structure and an amide structure in the molecule used in the flexible printed wiring board of the present invention may be manufactured by a method such as isocyanate method and an amine method (for example, acid chloride method, low-temperature solution polymerization method, room-temperature solution polymerization method), and may be formed from an aromatic diisocyanate; an aromatic tricarboxylic acid or its anhydride; and an aromatic dicarboxylic acid or its anhydride and/or an aromatic tetracarboxylic acid or its anhydride. In particular, the resin having both of an imide structure and an amide structure in the molecule used in the present invention is preferably soluble in organic solvents, and, from the viewpoint of industrial usefulness, is preferably manufactured by isocyanate method in which the reaction solvent during polymerization can be used as the organic solvent of the application solution.

In the case of isocyanate method, by reacting, as starting materials, trimellitic acid anhydride, an aromatic dicarboxylic acid, an aromatic tetracarboxylic acid dianhydride or the like, and aromatic diisocyanate compounds in an organic solvent, the resin having both of an imide structure and an amide structure in the molecule used in the present invention can be manufactured. Since in this reaction, carboxylic acid group and isocyanate group react almost stoichiometrically, the ratio of the charged starting materials can be set according to the ratio of an imide structure to an amide structure in the molecule of the resin to be manufactured.

As an example of aromatic diisocyanates used herein, 4,4′-bis(3-tolylene) diisocyanate, 3,3′-dichloro-4,4′-diisocyanate biphenyl, 1,4-naphthalene diisocyanate, 1,5-naphthalene diisocyanate, 2,6-naphthalene diisocyanate, 2,7-naphthalene diisocyanate, 4,4-diphenylmethane diisocyanate, 2,4-tolylene diisocyanate, 2,6-tolylene diisocyanate, p-xylene diisocyanate, 4,4′-diphenylether diisocyanate, p-phenylene diisocyanate, m-phenylene diisocyanate and others can be mentioned. They can be used singly or in combination.

Also, as an example of aromatic tricarboxylic acids or anhydrides thereof, trimellitic acid or its anhydride, diphenylether-tricarboxylic acid or its anhydride, diphenylsulfone-tricarboxylic acid or its anhydride, benzophenone-tricarboxylic acid or its anhydride, naphthalene-1,2,4-tricarboxylic acid or its anhydride, and ester compounds thereof can be mentioned. They can be used singly or in combination. In addition, a part of this aromatic tricarboxylic acid may be substituted by aliphatic tricarboxylic acids or anhydrides thereof such as butane-1,2,4-tricarboxylic acid or its anhydride, and ester compounds thereof.

Also, as an example of aromatic dicarboxylic acids or anhydrides thereof, terephthalic acid, isophthalic acid, biphenyl dicarboxylic acid, diphenylether dicarboxylic acid, diphenylsulfone dicarboxylic acid, and anhydrides thereof can be mentioned. They can be used singly or in combination. In addition, a part of this aromatic dicarboxylic acid may be substituted by aliphatic dicarboxylic acids such as adipic acid, azelaic acid and sebacic acid, and anhydrides thereof and ester compounds thereof; alicyclic dicarboxylic acids such as cyclohexane-4,4′-dicarboxylic acid, and anhydrides thereof and ester compounds thereof; and others.

In addition, as an example of aromatic tetracarboxylic acids or anhydrides thereof, pyromellitic acid or its dianhydride, benzophenone tetracarboxylic acid or its dianhydride, biphenyl tetracarboxylic acid or its dianhydride, diphenylether-3,3′,4,4′-tetracarboxylic acid or its dianhydride, ethyleneglycol bisanhydrotrimellitate, or the like can be mentioned. Furthermore, a part of this aromatic tetracarboxylic acid may be substituted by aliphatic tetracarboxylic acids such as butane-1,2,3,4-tetracarboxylic acid, anhydrides thereof, ester compounds thereof, cyclopentane-1,2,3,4-tetracarboxylic acid anhydrides, dianhydrides thereof, ester compounds thereof, and others. They can be used singly or in combination.

In the reaction above, the product is obtained by reacting the components described above in an organic solvent, generally in a temperature range of 10 to 200° C. for 1 to 24 hours. In the reaction, as a catalyst of the reaction between diisocyanate and carboxylic acid, for example, tertiary amines, alkali metal compounds, alkali earth metal compounds are preferably used.

Also, in the case of amine method, by reacting, as starting materials, trimellitic anhydride chloride, aromatic dicarboxylic chloride, aromatic tetracarboxylic acid dianhydride and aromatic diamine, in an organic solvent almost stoichiometrically, a resin having both of an imide structure and an amide structure in the molecule can be manufactured. As aromatic tetracarboxylic acid anhydride to be used herein, in the case of amine method, a resin having both of an imide structure and an amide structure in its molecule can be obtained by reacting, as starting materials, trimellitic anhydride chloride, aromatic dicarboxylic chloride, aromatic tetracarboxylic acid dianhydride, and aromatic diamine, in an organice solvent almost stoichiometrically. Herein, as aromatic tetracarboxylic acid anhydride, pyromellitic acid dianhydride, benzophenone tetracarboxylic acid dianhydride, biphenyl tetracarboxylic acid dianhydride, diphenylether-3,3′,4,4′-tetracarboxylic acid, ethyleneglycol bisanhydrotrimellitate, or the like; as aromatic dicarboxylic chloride, terephthalic acid chloride, isophthalic acid chloride, biphenyl dicarboxylic acid chloride, diphenylether dicarboxylic acid chloride, diphenylsulfone dicarboxylic acid chloride, or the like; as aromatic diamine, 1,4-naphthalene diamine, 1,5-naphthalene diamine, 2,6-naphthalene diamine, 2,7-naphthalene diamine, or the like can be used. These components can be used singly or in combination.

The reaction by the amine method described above is preferably performed in an organic solvent at a temperature of 0° C. to 100° C. for 1 hour to 24 hours.

An organic solvent used in the case of manufacturing a resin having both of an imide structure and an amide structure in the molecule described above using, for example, isocyanate method, is an organic solvent which can dissolve the resin having both of an imide structure and an amide structure in the molecule described above. As an example of such an organic solvent, N-methyl-2-pyrrolidone, N,N-dimethylformamide, N,N-dimethylacetoamide, 1,3-dimethyl-2-imidazolidinone, tetramethylurea, sulfolane, dimethylsulfoxide, γ-butylacetone, cyclohexanone, and cyclopentanone can be mentioned. Among them, N-methyl-2-pyrrolidone, N,N-dimethylformamide, and dimethylsulfoxide are preferable. Incidentally, in the present invention, a part of such suitable organic solvents as described above may be substituted by hydrocarbone-type organic solvents such as toluene and xylene; ether-type organic solvents such as diglyme, triglyme and tetrahydrofuran; ketone-type organic solvents such as methyl ethyl ketone and methyl isobutyl ketone.

In addition, when manufacturing a resin having both of an imide structure and an amide structure in the molecule used in the present invention, as acid components, the following components other than components described above may be mixed.

For example, as a tricarboxylic acid component, monoanhydride or ester compound of tricarboxylic acid such as diphenylether-3,3′,4′-tricarboxylic acid, diphenylsulfone-3,3′,4′-tricarboxylic acid, benzophenone-3,3′,4′-tricarboxylic acid, naphthalene-1,2,4-tricarboxylic acid, butane-1,2,4-tricarboxylic acid may be mentioned. They can be used singly or in combination.

Furthermore, in the present invention, together with diisocyanate compound described above, or in place of diisocyanate compounds in amine method, amines may be used.

As an example of amines which can be used in the present invention, 3,3′-dimethyl-4,4′-diaminobiphenyl, 3,3′-diethyl-4,4′-diaminobiphenyl, 2,2′-dimethyl-4,4′-diaminobiphenyl, 2,2′-diethyl-4,4′-diaminobiphenyl, 3,3′-dimethoxy-4,4′-diaminobiphenyl, 3,3′-diethoxy-4,4′-diaminobiphenyl, p-phenylenediamine, m-phenylenediamine, 3,4′-diaminodiphenylether, 4,4′-diaminodiphenylether, 4,4′-diaminodiphenylsulfone, 3,3′-diaminodiphenylsulfone, 3,41-diaminobiphenyl, 3,3′-diaminobiphenyl, 3,3′-diaminobenzanilide, 4,4′-diaminobenzanilide, 4,4′-diaminobenzophenone, 3,3′-diaminobenzophenone, 3,4′-diaminobenzophenone, 2,6-tolylene diamine, 2,4-tolylene diamine, 4,4′-diaminodiphenylsulfide, 3,3′-diaminodiphenylsulfide, 4,4′-diaminodiphenylpropane, 3,3′-diaminodiphenylpropane, 3,3′-diaminodiphenylmethane, 4,4′-diaminodiphenyl methane, p-xylene diamine, m-xylene diamine, 2,2′-bis(4-aminophenyl)propane, 1,3-bis(3-aminophenoxy)benzene, 1,3-bis(4-aminophenoxy)benzene, 1,4-bis(4-aminophenoxy)benzene, 2,2-bis[4-(4-aminophenoxy)phenyl]propane, bis[4-(4-aminophenoxy)phenyl]sulfone, bis[4-(3-aminophenoxy)phenyl]sulfone, bis[4-(3-aminophenoxy)phenyl]propane, 4,4′-bis(4-aminophenoxy)biphenyl, 4,4′-bis(3-aminophenoxy)biphenyl, tetramethylene diamine, hexamethylene diamine, isophorone diamine, 4,4′-dicyclohexylmethane diamine, cyclohexane-1,4-diamine, and diaminocyclohexane can be mentioned. They can be used singly or in combination. Of course, diisocyanates corresponding to the amines described above can be used.

The molecular weight of the resin having both of an imide structure and an amide structure in the molecule thus obtained is equivalent to preferably 0.3 to 2.5 dl/g, as logarithmic viscosity measured in N-methyl-2-pyrrolidone (polymer concentration: 0.5 g/dl) at 30° C., and particularly preferably 0.3 to 2.0 dl/g. When a resin having lower logarithmic viscosity than the limit described above is used, a film having sufficient mechanical properties is hardly formed. On the other hand, when a resin having both of an imide structure and an amide structure in the molecule having higher logarithmic viscosity than the limit described above is used, the viscosity of the dissolved organic solvent solution becomes significantly high and the application and processing become difficult.

A substrate layer that is an insulating layer of a flexible printed wiring board of the present invention is, for example, a resin having both of an imide structure and an amide structure in the molecule thus obtained, and is generally a polymer having a structure represented by the following formula (1) in the molecule.

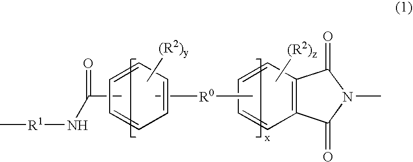

In the formula (1), R⁰ represents any of a divalent hydrocarbon group, a carbonyl group, an oxygen atom, a sulfur atom, sulfur oxide and a single bond; R¹ represents a divalent aromatic hydrocarbon group optionally having an aliphatic hydrocarbon group; R² each independently represents a monovalent hydrocarbon group; x is 0 or 1; y is any of 0, 1, 2, 3 and 4; and z is any of 0, 1, 2 and 3.

Resins having a structure represented by the above-mentioned formula (1) used in the present invention have a tendency that water absorption becomes smaller when x is 1 in formula (1) than when x is 0. Especially, when R⁰ is a divalent hydrocarbon group, the tendency is significant. As examples of R⁰ being a divalent hydrocarbon group, —(CH₂)—, —C(CH₃)₂— and the like can be mentioned.

Furthermore, in the above formula (1), R¹ is a divalent aromatic hydrocarbon group, and this R¹ may have an aliphatic hydrocarbon group. That is, a hydrogen atom on the aromatic ring may be substituted by an aliphatic hydrocarbon group such as methyl group, and two or three or more aromatic rings may be bonded by a divalent aliphatic hydrocarbon group such as methylene group. When the number of aromatic rings included in R¹ becomes larger, water absorption becomes lower and the resin becomes more easily dissolved in organic solvents.

In addition, in formula (1), an example of R² is a monovalent hydrocarbon group such as methyl group and ethyl group. When such R² exists, this part becomes bulky, and the resin becomes easily dissolved in solvents, thus crystallinity of the resin can be adjusted.

Especially in the present invention, a skeletal structure represented by the above formula (1) preferably has a skeletal structure represented by the following formula (1-1) or (1-2).

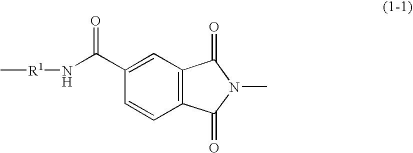

In the above formula (1-1), R¹ is a divalent aromatic hydrocarbon group which may have an aliphatic hydrocarbon group.

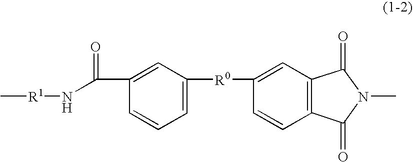

In the above formula (1-2), R⁰ represents any of a divalent hydrocarbon group, a carbonyl group, an oxygen atom, a sulfur atom, sulfur oxide and a single bond; R¹ represents a divalent aromatic hydrocarbon group optionally having an aliphatic hydrocarbon group. In the present invention, R⁰ in formula (1-2) is preferably any of divalent hydrocarbon group such as methylene group, ethylene group, and dimethylmethylene group, oxygen atom, and single bond.

A resin having both of an imide structure and an amide structure in the molecule used in the present invention is a resin having a structure represented by the above formula (1) as its basic skeleton, and is preferably a resin having a structure represented by formula (1-1) and/or formula (1-2). In the basic skeleton represented by the above formula (1), or formula (1-1) or formula (1-2), there exist an amide structure and an imide structure in a ratio of 1:1. When a resin having only such basic skeleton is used, a dense wiring pattern is hardly formed, even if an electrodeposited copper foil (a low profile electrodeposited copper foil) having S side and M side with different surface roughness, the surface roughness (Rzjis) of the M side that is a deposition plane of less than 1.0 μm and the glossiness of the M side [Gs(60°)] of 400 or more used in the present invention is laminated. Therefore, in the present invention, together with the structure represented by formula (1) or formula (1-1) and/or formula (1-2) described above, a resin having the structure represented by the following formulas (2) to (5), and furthermore formulas (6) to (7) is used.

That is, a resin having both of an imide structure and an amide structure in the molecule which forms a substrate layer to be an insulating layer in the present invention preferably has at least one structure selected from the group consisting of structures represented by the following formulas (2) to (5). By the combination of such structures, although not exhibiting such significantly high heat resistance as that of polyimide resin, it exhibits extremely high heat resistance as a thermoplastic resin, and is excellent in chemical resistance such as alkali resistance and acid resistance, and has a good balance of heat resistance, chemical resistance, electric properties and others. When structures represented by formulas (6) to (7) are incorporated, heat resistance is improved as well as water absorption tends to become lower. Moreover, when forming a wiring pattern by etching an electrodeposited copper foil into a desired pattern, a wiring pattern with very sharp shape can be formed. Particularly, by using the electrodeposited copper foil having such large particle diameter and low surface roughness as used in the present invention, a wiring pattern with very high accuracy can be formed.

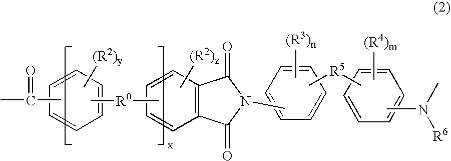

In the above formula (2), R⁰ represents any of a divalent hydrocarbon group, a carbonyl group, an oxygen atom, a sulfur atom, sulfur oxide and a single bond; R², R³ and R⁴ each independently represent a monovalent aliphatic hydrocarbon group; R⁵ represents a divalent hydrocarbon group; R⁶ represents a hydrogen atom or a monovalent aliphatic hydrocarbon group or forms a imide structure in cooperation with N; n and m each are independently any of 0, 1, 2, 3 and 4; x is 0 or 1; y is any of 0, 1, 2, 3 and 4; and z is any of 0, 1, 2 and 3.

As a preferable example of the structure represented by the above formula (2), structures represented by the following formula (2-1) and formula (2-2) can be mentioned.

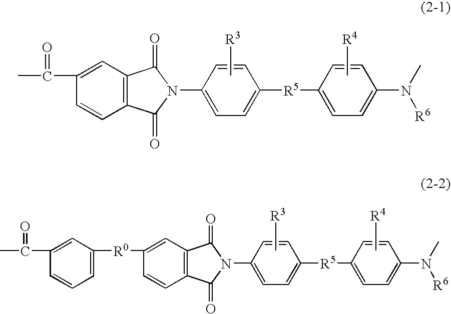

In the above formula (2-1) and formula (2-2), R⁰ represents any of a divalent hydrocarbon group, an oxygen atom and a single bond; R³ and R⁴ each independently represent a monovalent aliphatic hydrocarbon group, but, these R³ and R⁴ may exist or may not exist. When R³ and R⁴ do not exist, hydrogen atoms are bonded. When R³ and R⁴ exist, they can bond at ortho-position or meta-position of the aromatic ring for R⁵, but, they preferably bond at the meta-position. R⁵ represents a divalent hydrocarbon group, R⁶ represents a hydrogen atom or a monovalent hydrocarbon group or forms a imide structure in cooperation with N.

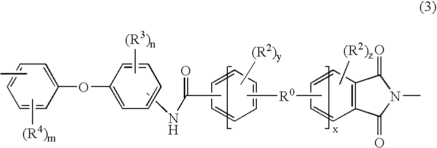

In the formula (3), R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; x is 0 or 1; y is any of 0, 1, 2, 3 and 4; and z is any of 0, 1, 2 and 3.

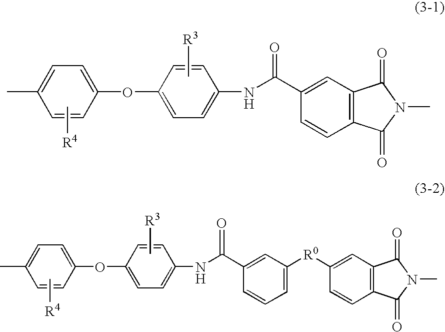

In the above formula (3-1) and formula (3-2), R⁰ represents any of a divalent hydrocarbon group, a carbonyl group, an oxygen atom, a sulfur atom, sulfur oxide and a single bond; R³ and R⁴ each independently represents a monovalent aliphatic hydrocarbon group, but, these R³ and R⁴ may exist or may not exist. When R³ and R⁴ do not exist, hydrogen atoms are bonded. When R³ and R⁴ exist, they can bond at ortho-position or meta-position of the aromatic ring for —O—, but they preferably bond at meta-position.

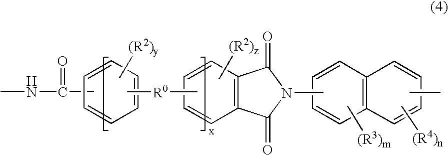

In the above formula (4), R⁰ represents any of a divalent hydrocarbon group, a carbonyl group, an oxygen atom, a sulfur atom, sulfur oxide and a single bond; R², R³ and R⁴ each independently represent a monovalent aliphatic hydrocarbon group; n and m each are independently any of 0, 1, 2, 3 and 4; x is 0 or 1; y is any of 0, 1, 2, 3 and 4; and z is any of 0, 1, 2 and 3.

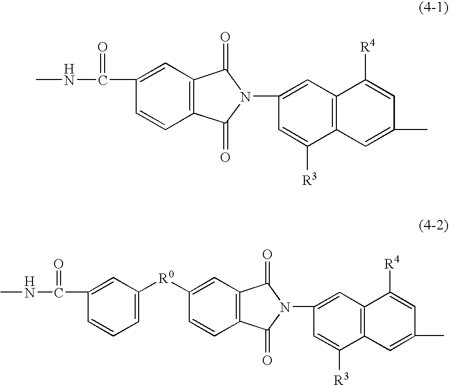

In the above formula (4-1) and formula (4-2), R⁰ preferably represents either a divalent hydrocarbon group or an oxygen atom. R³ and R⁴ each independently represent a monovalent aliphatic hydrocarbon group, but R³ and R⁴ may exist or may not exist. When R³ and R⁴ do not exist, hydrogen atoms are bonded. When R³ and R⁴ exist, their substituting positions are preferably positions shown in the above formula (4-1) or formula (4-2).

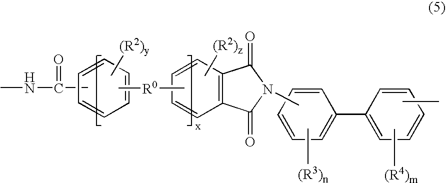

In the above formula (5), R⁰ represents any of a divalent hydrocarbon group, a carbonyl group, an oxygen atom, a sulfur atom, sulfur oxide and a single bond; R², R³ and R⁴ each independently represent a monovalent aliphatic hydrocarbon group; n and m each are independently any of 0, 1, 2, 3 and 4; x is 0 or 1; y is any of 0, 1, 2, 3 and 4; and z is any of 0, 1, 2 and 3.

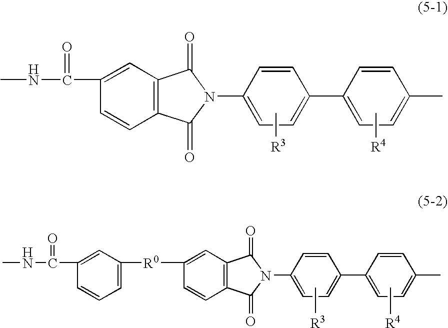

In the above formula (5-1) and formula (5-2), R⁰ represents a divalent hydrocarbon group or an oxygen atom; R³ and R⁴ each independently represent a monovalent aliphatic hydrocarbon group, but these R³ and R⁴ may exist or may not exist. When R³ and R⁴ do no exist, hydrogen atoms are bonded. When R³ and R⁴ exist, their substituting positions may be any positions

### <Linear Expansion Coefficient of the Resin Film>

By TMA (thermo-mechanical analysis/manufactured by Rigaku Co.) tensile load method, the linear expansion coefficient of the resin film obtained by removing the low-profile electrodeposited copper foil from the laminate was measured under the conditions described below. Firstly the film was heated in nitrogen gas, with a heating rate 10° C./min. up to the inflection point, and then cooled to room temperature. Hereafter the measurement was performed. Linear expansion coefficient of the resin film was 27 ppm/K.

Load: 5 g

Sample size: 4 mm (width)×20 mm (length)

Heating rate: 10° C./min.

Atmosphere: nitrogen gas

### <Linear Expansion Coefficient of the Low-Profile Electrodeposited Copper Foil>

By TMA (thermo-mechanical analysis/manufactured by Rigaku Co.) tensile load method, the linear expansion coefficient of the low-profile electrodeposited copper foil obtained by dissolving and removing the substrate layer from the laminate using N-methyl-2-pyrrolidone was measured. The linear expansion coefficient of the low-profile electrodeposited copper foil was 16 ppm/K. on the aromatic ring.

Structures represented by the above formulas (2) to (5) may exist in a resin having both of an imide structure and an amide structure in the molecule used in the present invention singly or in combination.

In addition, in the present invention, a resin having both of an imide structure and an amide structure in the molecule may have component units represented by the above formula (1) to formula (5) or formula (I-1) to formula (5-2) singly or in combination.

When structures represented by the following formulas (6) and (7) are incorporated into a resin having both of an imide structure and an amide structure in the molecule used in the present invention, balance of properties such as heat resistance, chemical resistance and mechanical strength becomes very excellent.

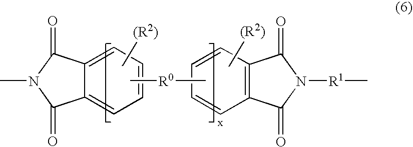

In the above formulas (6) to (8), R⁰ is a —CO— group or a single bond; R¹ each is independently any of groups represented by the following formula (a), formula (b) and formula (c); R² each is independently any of a hydrogen atom, a methyl group and an ethyl group.

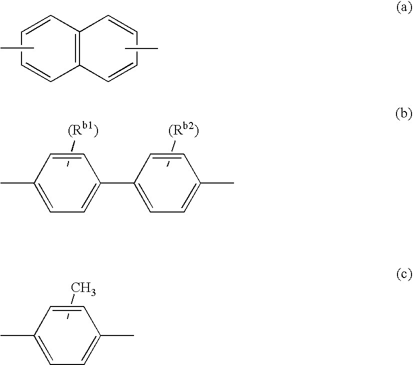

In the above formula (a), formula (b) and formula (c), R^{b1} and R^{b2} each are independently any of a hydrogen atom, a methyl group and an ethyl group.

In a resin having both of an imide structure and an amide structure in the molecule used in the present invention, the structures represented by the above formulas (1) to (5) and the structure represented by the above formula (6) are generally copolymerized in the ratio ranging from 95:5 to 70:30.

Furthermore, a resin having both of an imide structure and an amide structure in the molecule used in the present invention may contain a component unit represented by the following formula (7).

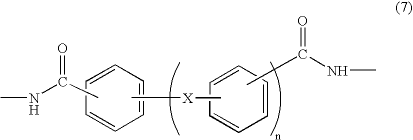

In the above formula (7), x represents an oxygen atom, CO, SO₂ or a single bond; n is 0 or 1.

As described above, each of formulas (1) to (5) or formulas (1-1) to (5-2) has an amide-imide skeletal structure. In the structure represented by formula (7), amide-bond is formed, but imide-bond is not formed. Conversely, in the structure represented by formula (6), amide-bond is not formed, but imide-bond is formed.

By introducing the component unit represented by formula (7) into the molecule, solubility to solvents, heat resistance of a resin having both of an imide structure and an amide structure in the molecule and the like can be adjusted. In addition, component units represented by formula (6) and formula (7) are usually incorporated in a resin having both of an imide structure and an amide structure in the molecule represented by formula (2), but component units represented by formula (6) and formula (7) may independently form a resin, or such resin may be blended into a resin having both of an imide structure and an amide structure in the molecule.

Properties of a substrate layer made of a resin having both of an imide structure and an amide structure in the molecule used in the present invention are affected by the ratio of the number of imide-structure to the number of amide-structure in the resin. In the present invention, by adjusting the ratio of the number of imide-structure (Iₙ) to the number of amide-structure (Aₙ) [(Iₙ)/(Aₙ)], heat resistance and thermoplasticity of the resin can be controlled. When this ratio [(Iₙ)/(Aₙ)] is maintained usually in the range of 20≧(Iₙ)/(Aₙ)>1, preferably in the range of 18≧(Iₙ)/(Aₙ)>1.1, a thermoplastic resin can be formed with keeping its excellent heat resistance, and the substrate layer never undergo thermal deformation at the bonding temperature of the flexible printed wiring board in the present invention. Moreover, this resin is dissolved into specific organic solvents to form an application solution having suitable viscosity that can be used in various application methods. When a substrate layer is formed by casting such a resin on the surface of an electrodeposited copper foil having such low surface roughness as described above, the application solution having a high affinity to the electrodeposited copper foil is required to use. However, by using a resin having a ratio of the number of imide-structure (Iₙ) to the number of amide-structure (Aₙ)[(Iₙ)/(Aₙ)] described above, an application solution having very high affinity to the electrodeposited copper foil and high uniformity can be prepared.

In a resin having both of an imide structure and an amide structure in the molecule for forming a substrate layer being an insulating layer in the present invention, a structure represented by formula (1), formula (1-1), formula (1-2), formula (2), formula (2-1), formula (2-2), formula (3), formula (3-1), formula (3-2), formula (4), formula (4-1), formula (4-2), formula (5), formula (5-1), formula (5-2), formula (6) and formula (7) can be formed by reacting corresponding to isocyanate component (or amine component) with carboxylic acid component. Components forming these structures have good reactivity and a charge amount of the components used as starting materials is approximately equal to the amount of the structures formed. The resin having both of an imide structure and an amide structure in the molecule has a good balance among heat resistance, chemical resistance and electric properties by having such structures described above. Especially, when an electrodeposited copper foil in which S side and M side have different surface roughness each other and the surface roughness (Rzjis) of the M side that is a deposition plane is less than 1.0 μm and the glossiness of the M side [Gs(60°)] is 400 or more is used, a high density wiring pattern in which the smallest pitch width at inner lead part is 35 μm or less, furthermore 30 μm or less can be formed. Moreover, the cross-sectional shape of thus formed wiring pattern shows a shape having a large etching factor and a very sharp wiring pattern can be formed. Also, diffusion of copper into thus formed insulating layer (substrate layer) hardly occurs and the insulating layer has very stable electric properties. In spite of such properties, when electronic components are mounted by abutting a bonding tool from the back side of the side where the wiring pattern is formed, the insulating layer does not melt by the heat from the bonding tool.

Moreover, by dissolving the resin in an organic solvent such as N-methyl-2-pyrrolidone and dimethylformamide, a uniform application solution can be prepared. By applying this solution on the surface of an electrodeposited copper foil and removing the solvents, an insulating layer having very high uniformity can be formed. Thus formed resin layer (substrate layer) has a high mechanical strength and can support the wiring pattern stably, even if the thickness of the substrate layer is 50 μm or less. That is, the thickness of the insulating layer that is a substrate layer made of a resin having both of an imide structure and an amide structure in the molecule is usually in the range of 5 to 125 μm, preferably in the range of 25 to 75 μm. A substrate layer with such thickness has excellent flexibility, and the obtained wiring board can be used in a folded state. In addition, since the substrate layer formed from the resin having such a constitution as described above has approximately the same linear expansion coefficient as that of the electrodeposited copper foil, the obtained printed wiring board hardly has deformation such as warpager and has excellent size accuracy. Therefore, a resin having both of an imide structure and an amide structure in the molecule and having each structure in the ratio described above is very suitable for forming an insulating layer of a printed wiring board such as a COF substrate in which device holes are not required to form and a film is formed by casting the above resin on one side of an electrodeposited copper foil.

In the present invention, by using a laminate formed by directly laminating a substrate layer made of a resin having both of an imide structure and an amide structure in the molecule described above and the specific electrodeposited copper foil, and by selectively etching the laminated electrodeposited copper foil, a flexible printed wiring board is manufactured.

The substrate layer made of a resin having both of an imide structure and an amide structure in the molecule is usually formed by applying the organic solvent solution of the resin having both of an imide structure and an amide structure in the molecule on the surface of the electrodeposited copper foil.

The layer of the resin having both of an imide structure and an amide structure in the molecule in the flexible printed wiring board of the present invention can be formed by applying a application solution in which the above resin is dissolved or dispersed in an amount of usually at 5 to 25 g, suitably 10 to 20 g based on 100 g of the organic solvent capable of dissolving the resin, on the surface of the electrodeposited copper foil, and drying. The application solution used herein is preferably a N-methyl-2-pyrrolidone solution of polyamide-imide, and its viscosity measured at 25° C. with B-type viscometer is preferably in the range of 1 to 1000 poise.

The polyamide-imide application solution may be applied on the surface of the electrodeposited copper foil by using a coating applicator, for example, roll coater, knife coater, doctor blade coater, gravure coater, die coater, reverse coater and the like.

The application solution is applied to make the thickness of the dry substrate layer in the range of 25 to 75 μm. When a substrate layer with such thickness is formed, a printed wiring board according to the present invention has excellent flexibility.

After applying the application solution as above, first drying is performed by increasing the temperature starting at a temperature 70° C. to 130° C. lower than the boiling point of the organic solvent contained in the application solution (in the above preferable example, N-methyl-2-pyrrolidone (boiling point=202° C.)), and then heating is performed at a temperature near the boiling point of the solvent or higher (secondary drying). If the temperature of the first drying is higher than the temperature 70° C. lower than the boiling point of the solvent foaming may occur on the application plate, the remaining amount of the solvent varies along the direction of thickness of the resin layer, and warpage deformation of the laminate is more likely to occur. On the other hand, if the drying temperature is lower than the temperature 130° C. lower than the boiling point of the solvent, drying time becomes longer and productivity decreases. As described above, the first drying is usually performed at 70 to 200° C. primarily for removing the solvent, and then the secondary drying is performed at a temperature of usually 300° C. or more by infrared heating.

Still more, the drying process of an application solution may be performed by, instead of using the first and secondary drying method, stepwise heating method. The latter method may be advantageously used in a reel treatment in which the film is wound to a reel.

As described above, the temperature range of the first drying varies depending on the type of organic solvent used, but is usually about 80 to 120° C. The time of the first drying under such conditions is set in order to make the ratio of remaining solvent in the film about 5 to 40 wt %, and is, in many cases, about 1 to 30 minutes, preferably about 2 to 15 minutes.

In addition, in the secondary drying, the remaining solvent is removed by heating to a temperature near or slightly higher than the boiling point of the solvent used. The temperature of the secondary drying is set generally in the range of 100° C. or higher to lower than 300° C., preferably in the range of 130 to 280° C. When the temperature of the secondary drying is lower than 100° C. the remaining ratio of the solvent in the substrate layer becomes high, and the properties of the resin having both of an imide structure and an amide structure in the molecule may not be sufficiently exhibited in the formed insulating layer. While, when the temperature exceeds 300° C., copper particles constituting the electrodeposited copper foil on which an application solution is applied, is recrystallized and properties of the electrodeposited copper foil is degraded. In order to prevent the degradation of properties due to the recrystallization of electrodeposited copper foil, the upper temperature limit of the secondary drying is preferably set to 280° C. or lower.

The time of the secondary drying under such conditions is set in order to make all the solvent substantially removed from the resin during the secondary drying.

Moreover, the above first and secondary drying may be performed in the air, but in consideration of variation of properties of the electrodeposited copper foil during the drying process, it is desirably performed in an inert gas atmosphere, preferably under reduced pressure, especially preferably under reduced pressure in an inert gas atmosphere. As an example of inert gas used herein, nitrogen, carbon dioxide, helium, argon and the like can be mentioned. When drying is performed under reduced pressure, the reduced pressure is about 10⁻⁵ to 10³ Pa, preferably about 10⁻¹ to 200 Pa.

The substrate layer formed by applying the application solution on the surface of the electrodeposited copper foil as described above is different from a polyimide layer in which application solution of polyimide precursor is applied and baked on the surface of the electrodeposited copper foil to form a polyimide layer, and removal of the solvent is sufficient to form the substrate layer having insulation properties, that is, an insulating layer. When forming an insulating layer using a resin having both of an imide structure and an amide structure in the molecule as mentioned above, an insulating layer made of the resin having both of an imide structure and an amide structure in the molecule (that is a substrate layer) can be formed only by removing the solvent of the application solution. Therefore, the drying temperature can be lowered, and by optimizing conditions of the first and the secondary drying as described above, organic solvents can be removed uniformly from the insulating layer that is a substrate layer formed by applying the resin having both of an imide structure and an amide structure in the molecule, and an insulating layer with high homogeneity can be formed.

A substrate layer made of a resin having both of an imide structure and an amide structure in the molecule constituting a flexible printed wiring board of the present invention has water absorption about 1.5% to 5% at normal temperature (25° C.) and change of size caused by water absorption is very low. In addition, linear expansion coefficient of a substrate layer made of a resin having both of an imide structure and an amide structure in the molecule (Lc-p) is usually 40 ppm/K or less, and may be lowered to about 16 ppm/K. By setting suitable conditions, linear expansion coefficient of a substrate layer made of a resin having both of an imide structure and an amide structure in the molecule constituting an insulating layer of a flexible printed wiring board of the present invention (Lc-p) can be made in the range of 5 ppm/K to 40 ppm/K. This linear expansion coefficient (Lc-p) is approximately the same as the linear expansion coefficient of copper (Lc-C). Accordingly, in a flexible printed wiring board of the present invention, even if temperature changes, the electrodeposited copper foil and the insulating film made of a polyamide-imide resin having both of an imide structure and an amide structure in the molecule exhibit almost the same behavior, warpage deformation of the printed wiring board due to temperature change hardly occurs, and the printed wiring board has very high size stability.

Such application solution containing a resin having both of an imide structure and an amide structure in the molecule as mentioned above becomes an insulating film by applying to the surface of a specific electrodeposited copper foil and removing the solvent. Therefore, there is no layer such as an adhesive layer between the insulating layer that is the substrate layer made of the resin described above and the electrodeposited copper foil.

An electrodeposited copper foil as described above has S side and M side having different surface roughness each other, and an application solution containing a resin having both of an imide structure and an amide structure in the molecule is applied to the surface having surface roughness (Rz) of 5 μm or less.

In general, an electrodeposited copper foil is manufactured by casting copper sulfate-type electrolyte between a rotation cathode having drum-shape and a lead-type anode or a dimension-stabilized anode (DSA) located at the opposite side of the rotation cathode, depositing copper on the surface of the rotation anode through electrolysis, and then continuously peeling off the deposited foil-like copper from the rotation cathode and winding. Thus obtained electrodeposited copper is wound to be a roll with predetermined width, and when its orientation is needed for specific measurement, orientation of rotation of the rotation cathode (orientation of the web's length) is called as MD (Machine Direction) and width orientation that is perpendicular to MD is called as TD (Transverse Direction).

The surface shape of electrodeposited copper foil, the side of which was contacted to the rotation cathode and peeled off, transcripts the surface shape of the mirror polished rotation cathode, and generally called as “shiny side” or “S side” since it is shiny. On the other hand, the surface state of the side which was deposition plane usually reflects the different crystal developing speeds of copper among crystals and has chevron bumpy shape, and this side is called as “deposition plane” or “M side”. In general, roughness of the deposition plane is larger than that of the shiny side, and this deposition plane (M side) is often roughened when the surface treatment of the electrodeposited copper foil is performed and becomes the laminating side with the insulating layer-constituting materials on manufacturing a copper laminate. To an electrodeposited copper foil, generally a surface treatment such as roughening to reinforce adhesive strength with the insulating layer-constituting materials through mechanical anchor effect and an anti-oxidation treatment is performed. Incidentally, roughening may not be performed according to a specific use.

In a laminate used for manufacturing a flexible printed wiring board of the present invention, an electrodeposited copper foil produced as described above, having S side and M side, in which the adhesive side contacting with the substrate layer is M side, and the surface roughness (Rz) of the M side is 5 μm or less, preferably in the range of 0.3 to 1.5 μm can be used. By applying an application solution containing a resin having both of an imide structure and an amide structure in the molecule described above on the M side of an electrodeposited copper foil, vaporizing and removing the solvent, and forming a substrate layer that is an insulating layer, a laminate in which an electrodeposited copper foil and an insulating layer are directly laminated can be obtained. In this case, to M side that is the laminating side of the electrodeposited copper foil, in order to enhance the adhesiveness with an insulating layer, treatments which are usually performed to an electrodeposited copper foil such as bump-forming treatment, burning plating treatment, cover plating treatment and coupling treatment may be performed.

A flexible printed wiring board of the present invention can be formed by using an electrodeposited copper foil having surface roughness of M side of 5 μm or less as described above. However, particularly in the present invention, a low-profile electrodeposited copper foil is preferably used.

The low-profile electrodeposited copper foil in the present invention is an electrodeposited copper foil having surface roughness (Rzjis) of its deposition plane of less than 1.0 μm, preferably less than 0.6 μm, and glossiness [Gs(60°)] of M side of 400 or more, preferably 600 or more, and its surface roughness (Rzjis) of M side and S side is very low, and it has mirror glossiness as indicated by its glossiness.

The glossiness [Gs(60°)] of a low-profile electrodeposited copper foil suitably used in the present invention is the measured strength of light reflected at the reflection angle of 60° when measuring light is introduced with the incidence angle of 60° to the surface of electrodeposited copper foil.

The incidence angle herein is 0° in the direction perpendicular to the light incidence plane. In JIS Z 8741-1997, there is a description on five types of mirror glossiness measuring methods with different incidence angles, and there is also described that optimal incidence angle should be selected depending on the glossiness of the sample. It is considered that by setting the incidence angle of 60° in particular, various samples from samples with low glossiness to large glossiness can be measured. Accordingly, in the present invention, incidence angle of 60° is adopted for measurement of glossiness of a low-profile electrodeposited copper foil.

In general, for evaluation of smoothness of deposition plane of an electrodeposited copper foil, surface roughness (Rzjis) has been used. However, surface roughness (Rzjis) provides height-directional unevenness information only, and does not provide information such as cycle of unevenness and surface waviness. By adopting surface roughness (Rzjis) and glossiness, together with height-directional unevenness information of the electrodeposited copper foil, information such as cycle of unevenness and surface waviness that explains the electrodeposited copper foil as a whole can be obtained. In the present invention, not only the surface roughness (Rzjis) as local height-directional unevenness information of low-profile electrodeposited copper foil, but also the cycle of unevenness and the surface waviness on the total surface of low-profile electrodeposited copper foil, the surface uniformity, and the like can be defined.

In a low-profile electrodeposited copper foil used in the present invention, characteristics that surface roughness (Rzjis) of deposition plane is less than 1.0 μm and glossiness [Gs(60°)] of the deposition plane is 400 or more are satisfied. Also in the present invention, a low-profile electrodeposited copper foil in which surface roughness (Rzjis) is less than 0.6 μm and glossiness [Gs(60°)] of the deposition plane is 700 or more is preferably used. In addition, in the present invention, the upper limit of glossiness [Gs(60°)] has not been determined. Although larger glossiness [Gs(60°)] is desired, from the empirical point of view, manufacturing of an electrodeposited copper foil having glossiness [Gs(60°)] of more than 780 is impossible. Accordingly in the present invention, the upper limit of glossiness [Gs(60°)] is 780.

In the present invention, glossiness was measured according to JIS Z 8741-1997 in which measuring methods of glossiness are defined using a glossmeter type VC-2000 manufactured by Nippondenshoku Co.

In a laminate used for forming a flexible printed wiring board of the present invention, the thickness of a low-profile electrodeposited copper foil is usually 5 μm or more, preferably 8 μm or more. A low-profile electrodeposited copper foil used in the present invention has tendencies that when the thickness becomes larger, the surface roughness (Rzjis) of the deposition plane (M side) becomes lower and the glossiness [Gs(60°)] becomes larger. Therefore, when a thick low-profile electrodeposited copper foil is used, a printed wiring board having good properties such as electrical properties can be obtained. However, a printed wiring board of the present invention is a printed wiring board having flexibility. In order to ensure the flexibility on the printed wiring board, as a low-profile electrodeposited copper foil used in the present invention, a low-profile electrodeposited copper foil having a thickness of usually 3 to 18 μm, preferably 6 to 15 μm is easily handled and has very good balance among various properties such as flexibility and electrical properties which are exhibited on the printed wiring board obtained, thus the low-profile electrodeposited copper foil having a thickness in such a range is preferably used. In addition, a very thin low-profile electrodeposited copper foil having a thickness about 0.1 μm may be manufactured and can be used with careful handling.

When the glossiness [Gs(60°)] of the deposition plane of a low-profile electrodeposited copper foil used in the present invention is measured, the TD glossiness measured in transverse direction and the MD glossiness measured in machine direction can be measured separately, and the ratio, i.e., [(TD glossiness)/(MD glossiness)] is in the range of 0.9 to 1.1. This means that the difference between the transverse direction and the machine direction is very small in a low-profile electrodeposited copper foil used in the present invention.

That is, in a low-profile electrodeposited copper foil used in general, it is a commonplace assumption that mechanical properties are different between the transverse direction (TD) and the machine direction (MD) due to the effects of the polish lines and the like on the surface of the rotating drum of cathode, but the low-profile electrodeposited copper foil used in the present invention has uniform and smooth surface on the deposition plane, regardless of the thickness, so that [(TD glossiness)/(MD glossiness)] is in the range of 0.9 to 1.1, and the fluctuation range is so small as within 10%. A low-profile electrodeposited copper foil used in the present invention is characterized by having very small differences of the surface shape between TD and MD.

In addition, the fact that there hardly exist the apparent differences between TD and MD indicates that electrolysis is performed homogeneously and crystals are uniform. That is, small differences of mechanical properties such as tensile strength and elongation between TD and MD are indicated. When differences of mechanical properties between TD and MD are small, size variation of the substrate, linearity of the circuit and the like due to the directivity of a copper foil during manufacturing a printed wiring board are less affected. Incidentally, a rolled copper foil that is a typical example of a copper foil having smooth surface is known to have differences of mechanical properties between TD and MD due to the direction of the processing. Accordingly, in a flexible printed wiring board of the present invention, a rolled copper foil has such a large size variation and is not suitable for the application with fine patterns, especially for the application of COF substrates as a copper foil. In contrast, in a flexible printed wiring board of the present invention, TD and MD of the low-profile electrodeposited copper foil to be used are uniform even considering from the viewpoint of a crystal structure, and thus, the differences of the mechanical properties such as tensile strength and elongation between TD and MD of a low-profile electrodeposited copper foil are small, and the size variation of substrate, the linearity of circuit and the like due to the directivity of a copper foil during manufacturing a printed wiring board are less affected.

Also, in the present invention, for suitably using low-profile electrodeposited copper foils, the difference from the conventional electrodeposited copper foils can be more clearly understood by measuring glossiness [Gs(20°)] and glossiness [Gs(60°)] and comparing both of them. Specifically, a low-profile electrodeposited copper foil suitably used in the present invention has the relation that the glossiness [Gs(20°)] is larger than the glossiness [Gs(60°)] in the deposition plane described above. If the materials are the same, only one glossiness measurement with one of the incidence angles is expected to be sufficient. However, even though the materials are the same, if the reflection ratio varies depending on the incidence angles, the glossiness varies due to the change of spatial distribution of reflected light depending on the unevenness on the surface of the side to be measured.

As a result of considering these facts, the following relations were empirically obtained. When an electrodeposited copper foil has high glossiness and low surface roughness, glossiness [Gs(20°)]>glossiness [Gs(60°)]>glossiness [Gs(85°)] is satisfied; and when an electrodeposited copper foil has low glossiness and low surface roughness, glossiness [Gs(60°)]>glossiness [Gs(20°)]>glossiness [Gs(85°)] is satisfied; moreover when an electrodeposited copper foil has no glossiness and low surface roughness, glossiness [Gs(85°)]>glossiness [Gs(60°)]>glossiness [Gs(20°)] is satisfied. Based on these facts, the evaluation of smoothness by the relation with measurement value of glossiness at the different incidence angles, in addition to by the absolute value of glossiness with a certain incidence angle is considered to be very important.

In such a low-profile electrodeposited copper foil, not only the surface state of deposition plane (M side) but also the surface state of shiny side (S side) is important. The surface roughness (Rzjis) and the glossiness [Gs(60°)] that are almost equivalent to those of the deposition plane (M side) are required for the shiny side (S side) of a low-profile electrodeposited copper foil used in the present invention. That is, the surface roughness (Rzjis) and the glossiness [Gs(60°)] of the shiny side (S side) of a low-profile electrodeposited copper foil are preferably less than 2.0 μm and 70 or more, especially preferably less than 1.7 μm and 100 or more. The upper limit of the glossiness [Gs(60°)] is not especially restricted, but is usually about 500 empirically. In order to achieve the surface state of deposition plane (M side) described above, shiny side (S side) has preferably the following surface state. If the following conditions are not satisfied, the surface states in TD and MD tend to differ and mechanical properties such as tensile strength and elongation tend to differ between TD and MD. Since the surface state of the shiny side (S side) is transcription of the cathode drum on which copper deposits, the surface state of the shiny side (S side) is determined by the surface state of the cathode drum. Accordingly, when a very thin electrodeposited copper foil is manufactured, surface roughness (Rzjis) of the cathode drum is required to be less than 2.0 μm.

As mechanical properties of a low-profile electrodeposited copper foil used in the present invention at normal state (25° C.), tensile strength is 33 kgf/mm² or more, elongation is 5% or more. After heating (180° C.×60 minutes, atmosphere), tensile strength is preferably 30 kgf/mm² or more, elongation is preferably 8% or more.

By optimizing the manufacturing conditions, a low-profile electrodeposited copper foil may have more excellent mechanical properties such as tensile strength at normal state (25° C.) of 38 kgf/mm² or more, and after heating (180° C.×60 minutes, atmosphere) of 33 kgf/mm² or more. With such excellent mechanical properties, the low-profile electrodeposited copper foil can be used in a folded state in a flexible printed wiring board of the present invention.

In addition, linear expansion coefficient (Lc-C) of a low-profile electrodeposited copper foil used in the present invention is usually 10 to 20 ppm/K. As described above, linear expansion coefficient (Lc-p) of a substrate layer made of a resin having both of an imide structure and an amide structure in the molecule which is laminated to a low-profile electrodeposited copper foil may be in the range of 5 ppm/K to 40 ppm/K, and the ratio of linear expansion coefficient (Lc-p) of a substrate layer made of a resin having both of an imide structure and an amide structure in the molecule to linear expansion coefficient (Lc-C) of an electrodeposited copper foil [=(Lc-p)/(Lc-C)] may be adjusted to usually in the range of 0.2 to 5, preferably in the range of 0.3 to 3. Moreover, by adopting suitable conditions, the above ratio [(Lc-p)/(Lc-C)] can be approximately 1. Since, in a laminate of a substrate layer made of a resin having both of an imide structure and an amide structure in the molecule and a low-profile electrodeposited copper foil used for manufacturing a flexible printed wiring board of the present invention, both linear expansion coefficients are almost the same as described above, thermal deformation hardly occurs, and the size stability is very high.

A low-profile electrodeposited copper foil used in the present invention may not undergo any surface treatments as described above, but at least one kind of the surface treatment of either rust-proofing or treatment with silane coupling agents may be performed. The rust-proofing herein is performed to prevent oxidative corrosion on the surface of the low-profile electrodeposited copper foil so that problems do not occur during the manufacturing processes of the copper clad laminate or the printed wiring board. The rust-proofing is preferably not to inhibit the adhesion with the polyamide-imide constituting an insulating layer, and is to enhance the adhesion if possible. Specifically, as rust-proofing agents, either the organic rust-proofing agents such as benzothiazol, benzotriazol and imidazole, or the inorganic rust-proofing agents such as zinc, chromate and zinc alloy; or the combination thereof can be mentioned.

Also, treatment with silane coupling agents herein is performed after completion of rust-proofing to enhance the chemical adhesion with a substrate layer constituting an insulating layer.

In the present invention, as rust-proofing methods using organic rust-proofing agents, for example, dip coating of organic rust-proofing agent solution, showering application, electro-coating and the like can be mentioned. As rust-proofing methods using inorganic rust-proofing agents, electrolytic deposition of rust-proofing elements onto the electrodeposited copper foil, a method, so-called substitution deposition and the like can be mentioned. For example, in zinc rust-proofing treatment, zinc pyrophosphate plating bath, zinc cyanide plating bath, zinc sulfate plating bath and the like may be used. For example, in the case of zinc pyrophosphate plating bath, the concentrations are set as follows, zinc: 5 g/L to 30 g/L, potassium pyrophosphate: 50 g/L to 500 g/L; solution temperature: 20° C. to 50° C.; pH: 9 to 12; current density: 0.3 A/dm² to 10 A/dm².

Also, silane coupling agents which can be used in treatment with silane coupling agents are not particularly restricted, but considering properties of a resin having both of an imide structure and an amide structure in the molecule to be used as a constituting component of an insulating layer, plating solutions used in manufacturing processes of a flexible printed wiring board, and others, epoxy-type silane coupling agents, amine-type silane coupling agents, mercapt-type silane coupling agents and the like can be used. By using these silane coupling agents, treatment with silane coupling agents is performed by dip coating, showering application, electro-deposition and the like.

More specifically, a silane coupling agent having good affinity with a substrate layer made of a resin having both of an imide structure and an amide structure in the molecule constituting an insulating layer of a flexible printed wiring board of the present invention such as vinyltrimethoxysilane, vinylphenylmethoxysilane, γ-methacryloxypropylethoxysilane, γ-glycidoxypropylmethoxysilane, 4-glycidylbutylmethoxysilane, γ-aminopropyltriethoxysilane, N-β(aminoethyl)-γ-aminopropyltrimethoxysilane, N-3-(4-(3-aminopropoxy)butoxy)propyl-3-aminopropyltrimethoxysilane, imidazole silane, triazine silane, γ-mercaptopropyltrimethoxysilane and the like can be used.

The surface roughness (Rzjis) of the contacting side thus treated as above with a substrate layer being an insulating layer of a low-profile electrodeposited copper foil is preferably 1.5 μm or less. By adjusting the surface roughness to the above range, a surface treated copper foil which is suitable for forming a fine-pitch circuit can be obtained.

In addition, the glossiness [Gs(60°)] of the contacting side thus treated as above with a substrate layer being an insulating layer of a low-profile electrodeposited copper foil is preferably 250 or more. Since a rust-proofing treated film or a silane coupling agent treated film is formed by the above surface treatment, even if change of surface roughness is not detected, reflectance of light and others may vary when compared them between before and after the surface treatment. However, when the glossiness [Gs(60°)] obtained from the contacting side of surface treated electrodeposited copper foil maintains 250 or more, it is considered that the surface treatment film is formed with appropriate thickness.

To the above contacting side with an insulating layer of a low-profile electrodeposited copper foil thus treated, roughening may be performed. The roughening is performed by applying a known technique, and the minimum roughening is sufficient in combination with rust-proofing technique. In forming fine pitch wiring having less than 40 μm pitch, preferably less than 25 μm pitch in which the surface treated low-profile electrodeposited copper foil is suitably used in the present invention, if the roughening is not performed, the accuracy for setting the overetching time required can be improved.

In the present invention, when a low-profile electrodeposited copper foil is roughened for use, either a method of adhesion of fine metal particles to the surface of low-profile electrodeposited copper foil or a method of forming the roughened surface by etching is adopted. A method of adhesion of fine metal particles to the surface of an electrodeposited copper foil is explained as an example of roughening methods as follows: the roughening process is composed of a step of depositing fine copper particles on the surface of electrodeposited copper foil to adhere and a step of cover-plating to prevent the dropping of copper particles.

In the step of depositing fine copper particles on the surface of electrodeposited copper foil to adhere, conditions for burning plating are adopted as the electrolysis conditions. Therefore, generally the concentration of the solution used in the step of depositing fine copper particles to adhere is adjusted low in order to obtain the conditions for burning plating easily. The conditions for burning plating may be set variously, for example, when sulfuric acid-type copper solution is used, the conditions are as follows: copper concentration: 5 to 20 g/L, free sulfuric acid concentration: 50 to 200 g/L, a blend of additives (α-naphthoquinoline, dextrin, glue, thiourea and the like) if needed; solution temperature: 15 to 40° C.; current density: 10 to 50 A/dm².

The step of cover-plating to prevent the dropping of copper particles is a step of depositing copper uniformly to cover fine copper particles under smooth plating conditions. Accordingly, the same copper electrolyte as used in the manufacturing process of an electrodeposited copper foil described above can be used as a source of copper ion. The conditions for smooth plating are not particularly restricted and may be determined considering the characteristics of production line. For example, when a sulfuric acid-type copper solution is used, conditions are as follows: copper concentration; 50 to 80 g/L, free sulfuric acid concentration: 50 to 150 g/L; solution temperature: 40 to 50° C.; current density: 10 to 50 A/dm².

The adhesive side with polyamide-imide that is a material for constituting an insulating layer of the surface treated low-profile electrodeposited copper foil used during the manufacturing of a flexible printed wiring board of the present invention is preferably deposition plane (M side). As described above, since surface state of the shiny side (S side) is transcription of cathode drum, complete elimination of difference between TD and MD nothing is difficult. In order to minimize the variation of linearity at the end of the wiring, which is caused when the surface shape of adhesive side has directivity in TD and MD, the deposition plane (M side) is preferably selected as the adhesive side.

A low-profile electrodeposited copper foil used in the present invention is obtained by peeling off the deposited copper foil on cathode surface by an electrolytic method using a sulfuric acid-type copper electrolyte. The sulfuric acid-type copper electrolyte used herein is obtained from, for example, at least one selected from MPS represented by the following formula (12) or SPS represented by the following formula (13), and a sulfuric acid-type copper electrolyte containing quaternary ammonium hydrochloride having a ring structure represented by the following formula (14). By using a sulfuric acid-type copper electrolyte having such composition, stable production of a low-profile electrodeposited copper foil used in the present invention becomes possible.

In addition, by optimizing electrolysis conditions, a low-profile electrodeposited copper foil in which glossiness [Gs(60°)] is larger than 700 can be obtained. In the sulfuric acid-type copper electrolyte, copper concentration is in the range of 40 g/L to 120 g/L, preferably in the range of 50 g/L to 80 g/L, and free sulfuric acid concentration is in the range of 60 g/L to 220 g/L, preferably in the range of 80 g/L to 150 g/L.

The total concentration of MPS and/or SPS contained in a sulfuric acid-type copper electrolyte used for manufacturing a low-profile electrodeposited copper foil used in the present invention is usually in the range of 0.5 ppm to 100 ppm, preferably in the range of 0.5 ppm to 50 ppm, more preferably in the range of 1 ppm to 30 ppm. When the total concentration of MPS and/or SPS is less than 0.5 ppm, surface roughness of deposition plane (M side) of the electrodeposited copper foil becomes large and a low-profile electrodeposited copper foil is hardly obtained. On the other hand, when the total concentration of MPS and/or SPS is more than 100 ppm, the effect of smoothing a deposition plane (M side) of the obtained electrodeposited copper foil is not improved, only to increase cost for liquid-waste disposal. By the way, in the present invention, MPS and SPS include their salts, and their concentration values described is the converted values as “sodium 3-mercapto-1-propane sulfonate (MPS-Na)” of a sodium salt. In a sulfuric acid-type copper electrolyte, MPS dimerizes to form a SPS structure. Accordingly, the concentration of MPS or SPS is the concentration including 3-mercapto-1-propane sulfonic acid momomer or salts such as MPS-Na, and an additive as SPS, and denatured materials that are added to the electrolyte as MPS and polymerized into SPS or the like. The structure of MPS is shown in formula (12) and the structure of SPS is shown in formula (13). From these formulas, it is indicated that SPS is a dimer of MPS.

HS—CH₂—CH₂—CH₂—SO₃⁻ (12)

SO₃⁻—CH₂—CH₂—S—S—CH₂CH₁₂CH₂—SO₃⁻ (13)

In a sulfuric acid-type copper electrolyte used for manufacturing a low-profile electrodeposited copper foil used in the present invention, polymer of quaternary ammonium salt having a ring structure is contained with a concentration usually in the range of 1 ppm to 150 ppm, preferably in the range of 10 ppm to 120 ppm, more preferably in the range of 15 ppm to 40 ppm. As a polymer of quaternary ammonium salt having a ring structure, various compounds may be exemplified, but considering the effect on forming a deposition plane of a low-profile, DDAC polymer is preferably used. DDAC forms a ring structure when forming a polymerization structure, and part of the ring is constituted by a nitrogen atom of the quaternary ammonium. DDAC polymer is considered to be any of four-membered ring to seven-membered ring or their mixture. Here as the typical example of the polymer, a compound having five-membered ring structure is shown in formula (14). It will be clearly understood from formula (14) that DDAC polymer has a polymer structure of dimmer or more of DDAC.

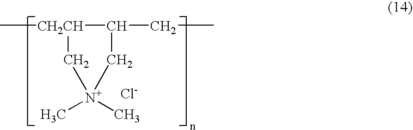

In the above formula (14), n is an integer of 2 or more.

When manufacturing a low-profile electrodeposited copper foil used in the present invention, the concentration of DDAC polymer in a sulfuric acid-type copper electrolyte is usually in the range of 1 ppm to 150 ppm, preferably in the range of 10 ppm to 120 ppm, particularly preferably in the range of 15 ppm to 40 ppm. When the concentration of DDAC polymer is less than 1 ppm, even if the concentration of MPS or SPS is raised, the surface roughness of deposition plane of the electrodeposited copper becomes large, and thus a low-profile electrodeposited copper foil is hardly obtained. When the concentration of DDAC polymer in a sulfuric acid-type copper electrolyte exceeds 150 ppm, the depositing state of copper becomes unstable and a low-profile electrodeposited copper foil is hardly obtained.

Also, the concentration of chloride in the above sulfuric acid-type copper electrolyte is preferably 5 ppm to 120 ppm, more preferably 10 ppm to 60 ppm. When the chloride concentration is less than 5 ppm, the surface roughness of deposition plane of the electrodeposited copper foil becomes large, and thus the low-profile is hardly maintained. On the other hand, when the concentration exceeds 120 ppm, the surface roughness of deposition plane of the electrodeposited copper foil becomes large, so that the electrodeposited state becomes unstable, and the low-profile deposition plane is hardly formed.

As described above, in order to form a low-profile electrodeposited copper foil, the balance among the concentrations of MPS or SPS, DDAC polymer, and chloride in the above sulfuric acid-type copper electrolyte is important, and when the quantitative balance among these concentration deviates from the above range, the surface roughness of deposition plane of the electrodeposited copper foil becomes large, so that a low-profile electrodeposited copper foil is hardly obtained.

When manufacturing a low-profile electrodeposited copper foil by using the above sulfuric acid-type copper electrolyte, the cathode with the surface roughness adjusted within the predetermined range and the insoluble anode is required for copper electrodeposition, and the electrolytic deposition of copper is performed under the following conditions, solution temperature: usually in the range of 20° C. to 60° C., preferably in the range of 40° C. to 55° C.; current density: usually in the range of 15 A/dm² to 90 A/dm², preferably in the range of 50 A/dm² to 70 A/dm².

Incidentally, when manufacturing a low-profile electrodeposited copper foil used in the present invention, the surface state of the cathode drum to be used should be controlled in order to obtain the properties required for the above electrodeposited copper foil stably. Referring to JIS C 6515 that is a standard of electrodeposited copper foils for printed wiring boards, the upper limit of the surface roughness (Rzjis) of shiny side required for electrodeposited copper foils is provided to be 2.4 μm. The cathode used for manufacturing the electrodeposited copper foil is a rolling cathode drum made of titanium (Ti), and changes in appearance and changes in metal layer occur due to surface oxidation during the continuous use. Accordingly, in order to manufacture a electrodeposited copper foil having high smoothness, it is preferable to smooth the surface of a rolling cathode drum periodically, and if needed, the surface polish, and furthermore the mechanical treatment such as polishing or cutting are required. Since such mechanical treatment is performed while rolling the cathode, streaky trace in the circumference direction is inevitably generated. Therefore, it is difficult to keep the steady state while maintaining the low surface roughness (Rzjis). The above standard is accepted with a prerequisite that there are no problems on the cost and the properties of a printed wiring board.

Conventional electrodeposited copper foils have a tendency that the larger the thickness, the larger the surface roughness of deposition plane (M side) becomes. It is empirically understood that the electrodeposited copper foils obtained by using a cathode drum having the surface roughness that is equal or larger than the upper limit of the above standard tends to have a large surface roughness of deposition plane (M side) due to the influence of the surface shape of the cathode. In contrast, when manufacturing a low-profile electrodeposited copper foil used in the present invention, by using the above sulfuric acid-type copper electrolyte, the influence of the surface shape of cathode is reduced during the thickening process of filling the unevenness on the surface of cathode, and an electrodeposited copper foil having smooth deposition plane can be obtained.

When the surface roughness (Rzjis) of deposition plane (M side) is lower than 1.0 μm in a electrodeposited copper foil having a thickness of less than 20 μm, it is preferable to use a cathode drum having a surface state by which a electrodeposited copper foil having a surface roughness (Rzjis) of shiny side (S side) of less than 2.0 μm, preferably less than 1.2 μm, and a glossiness [Gs(60°)] of 70 or more, preferably 120 or more, can be obtained, from the viewpoint of the mechanical properties and the minimization of the surface difference between TD and MD as described above.

In the above low-profile electrodeposited copper foil used in the present invention, the surface roughness of deposition plane (M side) of the low-profile electrodeposited copper foil is usually lower than that of shiny side (S side) which is transcription of a surface state of cathode drum, that is, the deposition plane is more smooth.

A flexible printed wiring board of the present invention is manufactured by using a laminate of the above low-profile electrodeposited copper foil and a substrate layer made of a resin having both of an imide structure and an amide structure in the molecule, and by selectively etching the laminated low-profile electrodeposited copper foil and forming a wiring pattern.

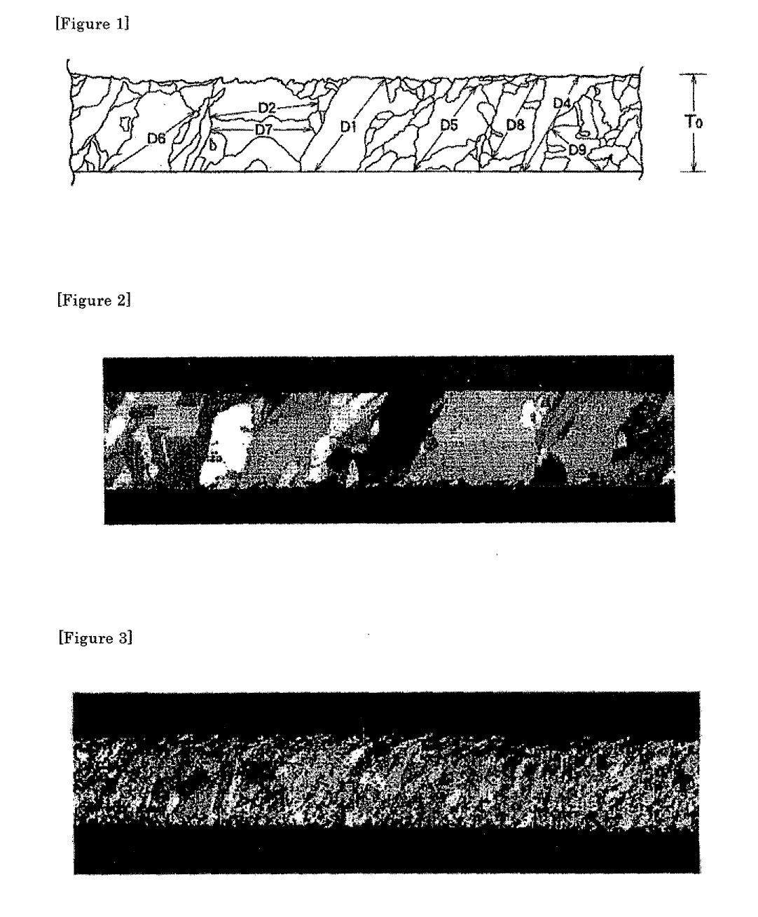

In the above laminate, the mean thickness of the low-profile electrodeposited copper foil is usually in the range of 5 to 25 μm, preferably in the range of 7 to 18 μm. A cross-sectional photograph of the above laminate is shown in FIG. 1.

FIG. 1 is an electron microscope photograph of a cross-section of inner lead formed by using the above low-profile electrodeposited copper foil (the substrate layer is dissolved and removed), which is differentiated by assorting the copper crystal particles from each crystal clearly, and its traced drawing.

In a low-profile electrodeposited copper foil used in the present invention, many columnar copper crystal particles having large particle diameter are formed unlike the conventional electrodeposited copper foil having small copper crystal particles, and among the columnar copper crystal particles, there exist many copper crystal particles having a major axis of 3 μm or more, preferably 6 μm or more.

As shown in FIG. 1, the thickness of a low-profile electrodeposited copper foil used in the present invention is T₀. In the low-profile electrodeposited copper foil, there exist many columnar copper crystal particles having major axes represented by D₁, D₂, D₃, D₄, D₅, D₆, D₇ and D₈. These major axes, D₁, D₂, D₃, D₄, D₅, D₆, D₇ and D₈ of the columnar copper crystal particles are equal to or clearly larger than thickness T₀ of the low-profile electrodeposited copper foil. Accordingly, in a wiring pattern constituting a flexible printed wiring board of the present invention, there exist many columnar copper crystal particles having major axes larger than the thickness of the wiring pattern.

In a wiring pattern formed in a flexible printed wiring board of the present invention, based on area ratio, usually 50% or more, preferably 75% or more of columnar crystal particles having major axes which is equal to or larger than thickness T₀ of the low-profile electrodeposited copper foil (=thickness of the wiring pattern) are contained in cross-section of the wiring pattern.

Therefore, in the low-profile electrodeposited copper foil used in the present invention, based on area ratio, 50% or less, preferably 25% or less of copper crystal particles having major axes of smaller than 3 μm are contained, and these copper crystal particles having major axes of smaller than 3 μm are present to fill the interstices of columnar copper crystal particles usually having major axes of 3 μm or more.

Since the columnar particles having major axes are contained in the low-profile electrodeposited copper foil used in the present invention with a high ratio, the particle interface having small bonding strength lessens, and this low-profile electrodeposited copper foil has high tensile strength. For a low-profile electrodeposited copper foil used in the present invention, the tensile strength measured at 25° C. is usually 33 kgf/mm² or more, preferably 37 to 40 kgf/mm². In addition, the tensile strength measured after heating at 180° C. for 60 minutes is usually 30 kgf/mm² or more, preferably 33 to 40 kgf/mm². That is, a low-profile electrodeposited copper foil used in the present invention has very high tensile strength because it is mainly made of columnar copper crystal particles having major axes of 3 μm or more as described above.

Moreover, the elongation of this low-profile electrodeposited copper foil at 25° C. is 5% or more, preferably 10 to 15%, and the elongation after heating at 180° C. for 60 minutes is usually 8% or more, preferably 10 to 15%. That is, as described above, copper crystal particles constituting a low-profile electrodeposited copper foil used in the present invention have columnar crystal particle diameter and a shape with major axes of 3 μm or more, thus a very high elongation is obtained not only at a normal temperature, but also after heating at a high temperature.

The above laminate used for manufacturing a flexible printed wiring board of the present invention is a laminate of a low-profile electrodeposited copper foil and a substrate layer made of a resin described above. This laminate may be formed by placing a resin film made of a resin having both of an imide structure and an amide structure in the molecule on deposition plane (M side) of a low-profile electrodeposited copper foil and using roll-laminate method and the like, but in the present invention, it is preferably formed by casting method, i.e., by applying an application solution containing a resin having both of an imide structure and an amide structure in the molecule on deposition plane (M side) of a low-profile electrodeposited copper foil and removing the solvent. A flexible printed wiring board of the present invention is preferably formed as a chip on film (COF) substrate that is a flexible printed wiring board in which device holes are not formed in an insulating layer in which electronic components are mounted. In a COF substrate, by casting method, in which without providing through-holes and the like in a low-profile electrodeposited copper foil, a polyamide-imide application solution is cast on the entire deposition plane (M side) of a low-profile electrodeposited copper foil, and then the solvent is removed, an insulating layer made a resin having the particular structure described above is formed very efficiently.

Moreover, when forming an insulating layer by casting method, it is preferable that the first drying is performed at a temperature 70 to 130° C. lower than the boiling point of the organic solvent contained in application solution of the resin, then the secondary drying is performed by heating at a temperature near the boiling point of the solvent or higher than the boiling point. For example, even if N-methyl-2-pyrrolidone (boiling point: 202° C.) which is a good solvent for the resin having both of an imide structure and an amide structure in the molecule and has relatively high boiling point is used, the temperature of the secondary drying in which the temperature is high can be set usually in the range of 100° C. or higher to lower than 300° C., preferably in the range of 130 to 280° C.

Thus even at the secondary drying in which heating is performed at very high temperature, the maximum temperature may be set to lower than 300° C., preferably lower than 280° C. When manufacturing a flexible printed wiring board of the present invention, the laminate is exposed at the highest temperature in this secondary drying. However, according to the present invention, when an insulating layer is formed as a substrate layer by applying a application solution containing the above resin using a casting method, the maximum temperature is lower than 300° C. even when the laminate is heated at the highest temperature. The laminate made of an insulating layer and an electrodeposited copper foil does not have a heat history exceeding 300° C. for longer than 10 minutes. In the laminate comprising a low-profile electrodeposited copper foil, recrystallization of copper crystal particles does not occur and the properties of the low-profile electrodeposited copper foil is maintained until the end without impairing the excellent properties.

As described above, an application solution containing the resin described above is applied to deposition plane (M side) of the low-profile electrodeposited copper foil, and then through the first drying and the secondary drying, a substrate layer that is an insulating layer is formed on deposition plane (M side) of the low-profile electrodeposited copper foil, thus a laminate is formed.

At the edge of width direction of thus formed long film-like laminate (laminate tape), sprocket holes for transportation of the tape are provided, and then a photosensitive resin layer is formed on the surface of shiny side (S side) of the low-profile electrodeposited copper foil in the laminate tape and a mask having predetermined pattern is placed on the surface of the photosensitive resin layer, light exposure and development are performed on the photosensitive resin layer, and a pattern made of the cured photosensitive resin is formed, and then by using the pattern as a mask, etching the of low-profile electrodeposited copper foil is performed selectively to form a wiring pattern.

After formation of the wiring pattern by etching, the pattern made of the cured photosensitive resin used as a masking material can be easily removed by alkali washing and the like. Since the substrate layer constituting the insulating layer of the flexible printed wiring board of the present invention has excellent alkali resistance, the concentration of the alkali washing solution used for removing the masking material can be raised. Accordingly, the masking material can be removed in a shorter time. By shortening the contact time with the alkali washing solution, the substrate layer having excellent alkali resistance is hardly affected by the alkali washing solution.

After the formation of the wiring pattern on the surface of the substrate layer that is an insulating layer by etching a low-profile electrodeposited copper foil, a solder resist layer is formed with inner leads which is a connecting terminal for electronic components and outer leads which is a connecting terminal for outside to be exposed, or a coverlay instead of the solder resist layer is applied to protect the wiring pattern other than leads portion. On the surfaces of inner leads and outer leads which are not protected by the solder resist layer or the coverlay, a plating treatments is performed. There exist many types of plating treatments such as tin plating, gold plating, zinc plating, solder plating, Pb-free solder plating, nickel-gold plating and silver plating, and a required plated layer is formed according to the application of the flexible printed wiring board of the present invention. The thickness of the plated layer varies depending on the type of the plated layer, but is usually 0.2 to 2.0 μm.

A case in which a solder resist layer or coverlay is formed, and then plating treatment is performed is explained above. Alternatively, before a solder resist layer or a coverlay is formed, a thin plated layer is formed over the entire wiring pattern, the solder resist layer or the coverlay is formed, and then the plating treatment on exposed leads from the solder resist layer or coverlay may be performed again.

Also, before a solder resist layer or a coverlay is formed, a plated layer with a required thickness may be formed.

The formed flexible printed wiring board as described above is preferably a COF substrate in which device holes for mounting electronic components are not formed and a wiring pattern is formed on surface of an insulating layer.

When an electronic component is mounted on such COF substrate, the electronic component is placed on the COF substrate so that a bump electrode formed on the electronic component abuts on the inner lead of the wiring pattern, and from the back side of the substrate layer under the inner lead formed in the COF substrate, the inner lead and the bump electrode are heated through the substrate layer (insulating layer) with a bonding tool and electrically connected, and thus the electronic component is mounted on the COF substrate.

The heating temperature with a bonding tool varies depending on the bonding method, but is for example 100 to 300° C., and heating time is usually 0.2 to 2.0 seconds.

A flexible printed wiring board of the present invention, especially a COF substrate, is hardly damaged by heating with a bonding tool through the substrate layer that is an insulating layer as described above.

A flexible printed wiring board of the present invention, especially a COF substrate is used for mounting an electronic component which drives a display device such as PDP and liquid crystal. The COF substrate to be used in such application is often used folded at marginal part of the display device. Since the resin having both of an imide structure and an amide structure in the molecule that forms an insulating layer has very excellent flexibility, and the low-profile electrodeposited copper foil that forms the wiring pattern has high tensile strength and high elongation, the wiring pattern having very high flexibility can be formed. Especially when the insulating layer is formed by using the resin having both of an imide structure and an amide structure in the molecule by casting method, the laminate made of the low-profile electrodeposited copper foil and the substrate layer made of the resin having both of an imide structure and an amide structure in the molecule is not heated to the extent that recrystallization of the low-profile electrodeposited copper foil proceeds, variation of ratio of large crystals formed in the low-profile electrodeposited copper foil hardly occurs, and the excellent mechanical properties of the low-profile electrodeposited copper foil are directly taken over by the wiring pattern.

Moreover, the insulating layer of the flexible printed wiring board of the present invention is constituted by the resin having both of an imide structure and an amide structure in the molecule and having excellent heat resistance, and the light transmittance of the substrate layer formed from the resin having both of an imide structure and an amide structure in the molecule is 50 to 70% when the thickness is 40 μm. By transmitting the light from the upper side of printed wiring board, the positioning can be performed by recognizing the light which transmitted the part of printed wiring board in which a wiring pattern is not formed.

Since the insulating layer of the flexible printed wiring board of the present invention is formed by using the resin having both of an imide structure and an amide structure in the molecule, the heating temperature during the formation of the insulating layer is low, and thus the excellent mechanical properties of the low-profile electrodeposited copper foil are maintained until the end.

Therefore, the flexible printed wiring board of the present invention has a high heat resistance and the wiring pattern formed on it has excellent mechanical properties. The flexible printed wiring board is particularly suitable to be used as the COF substrate which mounts electronic components without providing device holes, and is widely used for mounting an electronic component which drives a display device and is often used in a folded state.

### EXAMPLES

The flexible printed wiring board of the present invention will be explained in more detail in the following by referring to the examples, but the of the present invention will not be limited to these.

### Example 1

As a sulfuric acid-type copper electrolyte, an electrolyte that is a copper sulfate solution (copper concentration: 80 g/L, free sulfuric acid concentration: 140 g/L, MPS-Na concentration: 7 ppm, DDAC polymer (manufactured by SENKA corporation, Unisence FPA100L) concentration: 3 ppm, chloride concentration: 10 ppm) was prepared.

In the manufacturing of a low-profile electrodeposited copper foil, the low-profile electrodeposited copper foil having the thickness of 15 μm was continuously manufactured by using a cathode of titanium drum and an anode of DSA, under conditions of a solution temperature of 50° C. and a current density of 60 A/dm².

Mean thickness of the obtained low-profile electrodeposited copper foil was 15.0 μm, and in the normal state, the tensile strength was 39 kgf/mm² and the elongation was 7.2%, and after the heating at 180° C. for 60 minutes, the tensile strength was 35 kgf/mm² and the elongation was 14%.

Moreover, the surface roughness (Rzjis) of deposition plane (M side) of this low-profile electrodeposited copper foil was 0.51 μm, and the surface roughness (Rzjis) of shiny side (S side) was 1.0 μm.

The linear expansion coefficient (Lc-C) of the low-profile electrodeposited copper foil was 16 ppm/K.

An electron microscope photograph of the surface of low-profile electrodeposited copper foil is shown in FIG. 2. For comparison, an electron microscope photograph of a commercially available electrodeposited copper foil having low surface roughness (surface roughness (Rzjis) of M side: 3.5 μm) is shown in FIG. 3.

Into a reaction vessel, trimellitic acid anhydride (TMA) 17.29 g (0.09 mol, manufactured by Mitsubishi Gas Chemical Company, Inc.), 3,3′,4,4′-biphenyltetracarboxylic acid dianhydride (BPDA) 2.94 g (0.01 mol), 1,5-naphthalenediphenylmethadiisocyanate 21.0 g (0.1 mol, manufactured by Sumitomo Bayer Urethane Co. Ltd.), diazabicycloundecene 1 g (manufactured by San-Apro Ltd.), and N-methyl-2-pyrrolidone (hereinafter, abbreviated as NMP in some cases) 233.6 g (manufactured by Dia Chemical Co. Ltd.) (polymer concentration: 15%) were added and heated to 100° C. over 2 hours and reacted for 5 hours.

Then NMP 68.6 g (polymer concentration: 12%) was added and was cooled to room temperature.

In the resulting polymerization reaction solution, a brownish-yellow-colored polymer (a resin having both of an imide structure and an amide structure in the molecule) was dissolved in NMP. This solution was used as an application solution.

By using thus obtained application solution, on the deposition plane (M side) of the above low-profile electrodeposited copper foil, the application was performed with a knife coater so that the thickness after drying was 40 μm. Then, drying at 100° C. was performed for 5 minutes, and a laminate to which first drying was performed was obtained.

The obtained laminate to which first drying was performed as described above was wound on an aluminum can having an inner diameter of 16 inches so that the applied surface becomes the outside and secondary drying was performed in a vacuum dryer or an inner oven by heating under the conditions as follows:

Drying condition under reduced pressure; 200° C.×24 hours (pressure varied between 10 and 100 Pa depending on the volatilization of the solvent);

Heating under nitrogen gas (nitrogen gas flow rate: 20 L/min.): 260° C.×3 hours. After secondary drying, the solvent in the film of the resulting laminate was removed completely.

From thus obtained laminate, samples were cut out, and the strength, the elongation and the elastic modulus were measured.

### <Strength, Elongation, Elastic Modulus of the Resin Film>

From the resin film obtained by removing the low-profile electrodeposited copper foil, samples with width 10 mm, length 100 mm were made and measured with a tensile tester (“Tensilon tensile tester”, manufactured by Toyo Baldwin Co.) (tensile speed: 20 mm/min., distance between chucks: 40 mm).

The tensile strength was 240 MPa, the elongation was 30%, and the elastic modulus was 4900 MPa.

### <Glass Transition Temperature (Tg)>

By TMA (thermo-mechanical analysis/manufactured by Rigaku Co.) tensile load method, the glass transition temperature (Tg) of the resin film obtained by removing the low-profile electrodeposited copper foil was measured under the conditions described below. Firstly the film was heated in nitrogen gas with a heating rate of 10° C./min. up to the inflection point, then cooled to room temperature. Hereafter the measurement was performed. Glass transition temperature of the resin having both of an imide structure and an amide structure in the molecule was 350° C. The glass transition temperature was measured by dynamic mechanical analysis (DMA method, Seiko Instruments Inc.).

Load: 5 g

Sample size: 4 mm (width)×20 mm (length)

Heating rate: 10° C./min.

Atmosphere: nitrogen gas

Load: 5 g

Sample size: 4 mm (width)×20 mm (length)

Heating rate: 10° C./min.

Atmosphere: nitrogen gas

### <Water Absorption>

According to IPC-FC241 (IPC-TM-650, 2.2.2 (c)), the water absorption of the substrate layer was measured by using the following method. When the roughness of cut plain of the sample is large, the plain was polished with a polishing paper p240 or more prescribed in JIS R 6252.

(1) A dry weighing bottle was dried in an oven heated at a temperature of 100° C. to 105° C. for 1 hour, and then cooled to room temperature in a desiccator, and weight of the weighing bottle (W0) was weighed accurately in the 0.0001 g unit, and the weighing bottle was returned to the desiccator.

(2) A dry substrate film (etching treated sample) was dried in an oven heated at a temperature of 105° C. to 110° C. for 1 hour, and its weight (W1) was weighed accurately in the 0.0001 g unit.

(3) The above substrate film was taken out of the weighing bottle (the weighing bottle was returned to the desiccator), and the humidity conditioning was performed in the atmosphere of 25° C.±1° C., 90% RH±3% RH for 24 hours±1 hour.

(4) After the humidity conditioning, the above substrate film was placed in the weighing bottle, stoppered tightly and cooled to room temperature in a desiccator, and then the weight (M1) was weighed accurately in the 0.0001 g unit. The weight (M0) of the weighing bottle was weighed immediately before the sample was placed therein.

(5) From the following formula, water absorption (WA, %) was determined.

WA(%) [(M1−M0)−(W1−W0)]×100/(M1−M0)

Thus measured water absorption of the substrate film was 3.05%.

On the surface (S side) of the low-profile electrodeposited copper foil in the laminate in which the low-profile electrodeposited copper foil having a thickness of 15 μm and the substrate film having a thickness of 40 μm (insulating layer) made of the above resin were laminated, a photosensitive resin was applied. Light exposure and development were performed to the photosensitive resin layer thus formed.

By using thus formed pattern as a masking material, the low-profile electrodeposited copper foil was selectively etched with a cupric chloride-type etching solution.

The wiring pitch width (P) of thus obtained inner leads was 20 μm, and the lead width (W) was 10 μm. Further, the wiring pitch width of the outer leads was 40 μm, and the lead width was 20 μm.

By alkali washing of the etched substrate film, the masking material was removed, and then a solder resist was applied to expose the inner leads and outer leads by using screen printing technique and dried, to form the solder resist layer.

Then, on the portion of the inner leads and outer leads exposed from the solder resist layer, electroless tin plating layer having a thickness of 0.5 μm was formed and a COF substrate that is a flexible printed wiring board of the present invention was prepared.

On the inner leads of thus obtained COF substrate, an electronic component (1280 ch/1 IC) was abutted and a bonding tool was abutted from the substrate layer (insulating layer) side of the COF substrate, and were heated with ultrasonic waves, and to prepare a semiconductor device mounted with an electronic component.

When manufacturing as described above, from the COF substrate before electroless tin plating layer was formed, inner leads were cut out. An electron microscope photograph of the cross-section of thus obtained inner leads is shown in FIG. 2. In FIG. 2, the substrate layer that is an insulating layer was dissolved and removed using a solvent. The traced drawing of the electron microscope photograph is also shown in FIG. 1.

As shown in FIG. 1, the thickness of the inner leads T₀ is 15 μm, and in the traced drawing of FIG. 1, D₁ to D₈ were columnar copper crystals having major axes obviously larger than T₀=15 μm of the thickness of inner leads. The occupation area of columnar copper crystals longer than 8 μm was 60% at this cross-section.

Moreover, in thus prepared COF substrate, the light transmittance of the substrate layer on which a wiring pattern is not formed among wiring patterns was 74% at 600 nm. In TAB bonding, a light source was placed on the upper side of the COF substrate, and a CCD camera was placed on the underside of the substrate layer that is an insulating layer, and by detecting the light which transmitted the COF substrate, the positioning between the semiconductor chip and the COF substrate could be performed.

In thus obtained COF substrate, the wiring resistance change was measured using a commercially available MIT tester which was a test apparatus for folding endurance, under the following conditions:

Load: 100 gf/10 mm²,

Flexure angle: ±135°,

Flexure radius: 0.8 mm,

Flexure speed: 175 rpm,

Temperature: 25° C.

As the result, the wiring broke at 130th flexure.

As shown in FIG. 1, copper particles at the cross-section of wiring pattern formed in a COF substrate that is a flexible printed wiring board of the present invention have much larger shape than conventional copper particles (refer to FIG. 3) constituting the widely used electrodeposited copper foils which is considered to be suitable for forming printed wiring boards. Moreover, such columnar copper particles having large particle diameters existing in large numbers are considered to provide excellent properties such as very excellent folding endurance, elongation and the like to the wiring pattern in cooperation with other columnar copper particles among wiring patters. In addition, as an insulating layer, by using a substrate layer made of a resin having both of an imide structure and an amide structure in the molecule, the heating temperature can be lowered during the formation of insulating layer, without changing the state of large copper crystals formed in a low-profile electrodeposited copper foil during the process of forming wiring boards, thus excellent properties inherent to the low-profile electrodeposited copper foil is maintained also in the printed wiring board.

### Comparative Example 1

As an electrodeposited copper foil, an ultra-low surface roughness electrodeposited copper foil (manufactured by Mitsui Mining & Smelting Co.) was used; on the S side of this electrodeposited copper foil, a varnish of polyimide precursor was applied; and then the copper foil is heated to prepare a two layer laminate.

The elongation of the electrodeposited copper foil measured at 25° C. was 4%, the tensile strength was 33 kgf/mm², the surface roughness (Rz) of S side was 1.0 μm, and glossiness [Gs(60°)] was 370.

The linear expansion coefficient of polyimide layer was 26 ppm/K and was significantly different from that of the electrodeposited copper foil.

Except for using the above electrodeposited copper foil, a wiring pattern was formed similarly to Example 1, and on the leads portion of the obtained wiring pattern, electroless tin plating layer having a thickness of 0.5 μm was formed.

The thickness of inner lead was 15 μm, and when observing the cross-section, almost 100% of the inner lead was constituted by copper crystal particles having particle diameter of smaller than 3 μm.

In thus obtained COF substrate which is a flexible printed wiring board, when a folding endurance test was performed using MIT tester, the wiring broke at the 60th flexure.

An insulating layer constituting a flexible printed wiring board of the present invention is formed by, for example, the above resin having both of an imide structure and an amide structure in the molecule. The resin having both of an imide structure and an amide structure in the molecule, although having a high heat resistance, may be processed into a film by heating at almost 250° C. and removing the solvent. In the film forming, since a film can be formed by removing the solvent contained in the application solution without performing a ring closure reaction on a copper foil as in the case of polyimide, an insulating layer can be formed at the temperature approximately 100° C. lower than the heating temperature (that is, baking temperature) compared with a conventional method in which a polyimide layer is formed by baking reaction using a polyimide that has been used conventionally in an insulating layer. Therefore, when the application solution containing the above resin having both of an imide structure and an amide structure in the molecule is applied on the above electrodeposited copper foil having low surface roughness, the film is formed as an insulating layer and the laminate is manufactured, the excellent properties inherent to the copper foil are maintained.

Although the resin having both of an imide structure and an amide structure in the molecule is thermoplastic, its melting point and softening point are very high. As in COF substrates, by heating the leads and the bump electrodes formed on the electronic components from the back side of an insulating layer through the insulating layer to perform an electrical bonding, the insulating layer made of the resin having both of an imide structure and an amide structure in the molecule is hardly damaged.

In addition, the substrate layer made of the resin having both of an imide structure and an amide structure in the molecule, that is, the insulating layer, has low water absorption, and its linear expansion coefficient may be almost the same as that of the copper foil, and thus the deformation of printed wiring board due to the difference of linear expansion coefficients hardly occurs.

Moreover, this resin having both of an imide structure and an amide structure in the molecule has excellent alkali resistance. For example, if this resin contacts with a strong alkali washing liquid for surface cleaning during the production process of the printed wiring board, the insulating film of the printed wiring board is not denatured. Therefore, a strong alkali washing liquid having stronger washing power can be contacted and printed wiring boards can be efficiently manufactured by shortening contact time with a strong alkali washing liquid. Also since the contact time with an alkali washing liquid is short, the alkali washing liquid hardly affects the printed wiring boards.

Accordingly, a flexible printed wiring board of the present invention has excellent properties such as mechanical properties, heat resistance, alkali resistance and the like, and especially suitable for a COF substrate.

1. A flexible printed wiring board, comprising:
a laminate formed by directly laminating an electrodeposited copper foil having S side and M side, each of S side and M side having a different surface roughness, and the surface roughness of the M side being 5 μm or less, on a surface of a substrate layer made of a resin having both of an imide structure and an amide structure in the molecule; and
a wiring pattern formed by etching the electrodeposited copper foil.

2. A flexible printed wiring board, comprising:
a laminate formed by directly laminating an electrodeposited copper foil having S side and M side, each of S side and M side having a different surface roughness, the surface roughness (Rzjis) of the M side of a deposition plain being 1.0 μm or less, and the glossiness of the M side [Gs(60°)] being 400 or more, on a surface of a substrate layer made of a resin having both of an imide structure and an amide structure in the molecule; and
a wiring pattern formed by etching the electrodeposited copper foil.

3. The flexible printed wiring board according to claim 1, wherein the resin forming the substrate layer is a resin formed by an aromatic diisocyanate, an aromatic tricarboxylic acid or its anhydride, an aromatic dicarboxylic acid and its anhydride, and/or an aromatic tetracarboxylic acid and its anhydride; and having an imide structure and an amide structure in the molecule.

4. The flexible printed wiring board according to claim 1, wherein a structure represented by the following formula (1) is formed in the resin for forming the substrate layer; 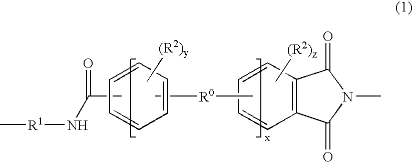
wherein R⁰ represents any of a divalent hydrocarbon group, a carbonyl group, an oxygen atom, a sulfur atom, sulfur oxide and a single bond; R¹ represents a divalent aromatic hydrocarbon group optionally having an aliphatic hydrocarbon group; R² each independently represents a monovalent hydrocarbon group; x is 0 or 1; y is any of 0, 1, 2, 3 and 4; and z is any of 0, 1, 2 and 3.

5. The flexible printed wiring board according to claim 1, wherein at least one structure selected from the group consisting of structures represented by the following formulas (2) to (5) is formed in the resin for forming the substrate layer; 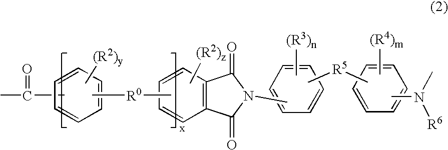
wherein R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; R⁵ represents a divalent hydrocarbon group; R⁶ represents a hydrogen atom or a monovalent aliphatic hydrocarbon group or forms a polyimide structure in cooperation with N; n and m each is independently any of 0, 1, 2, 3 and 4; x is 0 or 1; y is any of 0, 1, 2, 3 and 4; and z is any of 0, 1, 2 and 3; 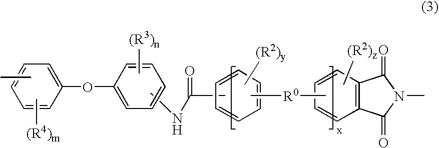
wherein R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; x is 0 or 1; y is any of 0, 1, 2, 3 and 4; and z is any of 0, 1, 2 and 3; 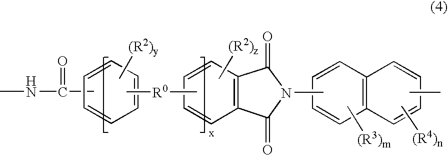
wherein R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; x is 0 or 1; y is any of 0, 1, 2, 3 and 4; and z is any of 0, 1, 2 and 3; 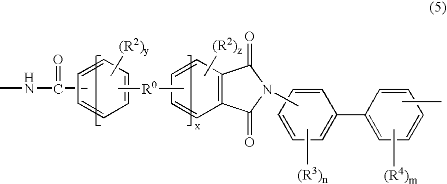
wherein R⁰ represents any of a divalent hydrocarbon group, a carbonyl group, an oxygen atom, a sulfur atom, sulfur oxide and a single bond; R², R³ and R⁴ each independently represents a monovalent aliphatic hydrocarbon group; n and m each is independently any of 0, 1, 2, 3 and 4; y is any of 0, 1, 2, 3 and 4; x is 0 or 1; and z is any of 0, 1, 2 and 3.

6. The flexible printed wiring board according to claim 1, wherein the resin forming the substrate layer is a copolymer of the structure represented by formula (1) and structures represented by the following formula (6), formula (7) or formula (8); 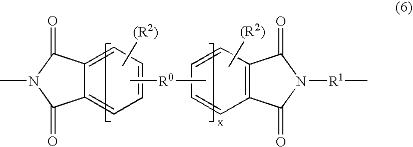
wherein R⁰ is a —CO— group or a single bond; R¹ is independently any group represented by the following formula (a), formula (b) and formula (c); R² each is independently any of a hydrogen atom, a methyl group, and an ethyl group; 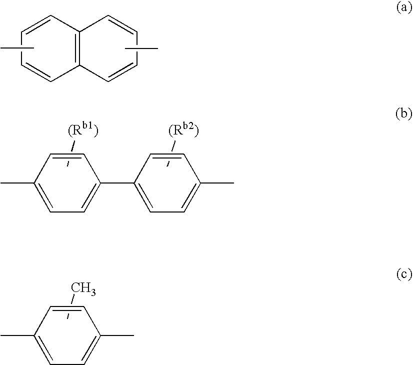
wherein R^{b1} and R^{b2} each is independently any of a hydrogen atom, a methyl group and an ethyl group.

7. The flexible printed wiring board according to claim 1, wherein the substrate layer is directly laminated on the M side of electrodeposited copper foil.

8. The flexible printed wiring board according to claim 1, wherein the substrate layer is formed on the M side of electrodeposited copper foil after surface roughening.

9. The flexible printed wiring board according to claim 1, wherein the surface roughness of the M side of electrodeposited copper foil is lower than that of the S side.

10. The flexible printed wiring board according to claim 2, wherein the average thickness of the electrodeposited copper foil is in the range of 5 to 18 μm, and at least a part of copper crystal particles forming the electrodeposited copper foil has larger particle diameter than the average thickness of the electrodeposited copper foil.

11. The flexible printed wiring board according to claim 2, wherein the laminate made of the substrate layer and the electrodeposited copper foil does not have a heat history of being exposed to a temperature of more than 300° C. for 10 minutes or more.

12. The flexible printed wiring board according to claim 2, wherein a tensile strength of the electrodeposited copper foil forming the laminate is 85% or more based on a tensile strength of the electrodeposited copper foil before forming the laminate, and 30 kg/cm² or more after forming the laminate.

13. The flexible printed wiring board according to claim 1, wherein a device hole for mounting an electronic component is not formed in the laminate comprising the substrate layer and the electrodeposited copper foil.

14. The flexible printed wiring board according to claim 2, wherein a thickness of the substrate layer is in the range of 30 to 45 μm, a thickness of the electrodeposited copper foil is in the range of 5 to 18 μm, a thickness of the laminate is in the range of 35 to 60 μm.

15. The flexible printed wiring board according to claim 1, wherein the substrate layer is formed by applying a solution containing a resin having both of an imide structure and an amide structure in the molecule on the M side of electrodeposited copper foil, and heating at temperature of 300° C. or lower.

16. The flexible printed wiring board according to claim 2, wherein the linear expansion coefficient (Lc-p) of the substrate layer is in the range of 5 to 30 ppm/K, and the ratio of the linear expansion coefficient (Lc-p) of the substrate layer to that of the electrodeposited copper foil (Lc-C=10 to 20 ppm/K)[(Lc-p)/(Lc-C)] is in the range of 0.99 to 1.4.

17. The flexible printed wiring board according to claim 1, wherein when the flexible printed wiring board has no device hole for mounting an electronic component, an electronic component is mounted by abutting a bonding tool on a resin film forming a substrate layer from a back side of the substrate layer, and heating a lead portion of a wiring pattern through the resin film forming the substrate layer.

18. A semiconductor device, comprising:
connecting electrically an electronic component to a lead portion of a wiring pattern formed on the flexible printed wiring board according to claim 1.

19. A semiconductor device, comprising:
connecting electrically an electronic component to a lead portion of a wiring pattern formed on the flexible printed wiring board according to claim 2.

20. The flexible printed wiring board according to claim 2, wherein a device hole for mounting an electronic component is not formed in the laminate comprising the substrate layer and the electrodeposited copper foil.
